(19) United States
(12) Patent Application Publication
(10) Pub. No.: US 2023/0037227 A1
(43) Pub. Date: Feb. 2, 2023

(54) DUAL EXPONENT BOUNDING BOX FLOATING-POINT PROCESSOR

(71) Applicant: Microsoft Technology Licensing, LLC, Redmond, WA (US)

(72) Inventors: Shankar S. Narayan, Saratoga, CA (US); Derek E. Gladding, Poughquag, NY (US); Tahsin Khan, San Jose, CA (US)

(73) Assignee: Microsoft Technology Licensing, LLC, Redmond, WA (US)

(21) Appl. No.: 17/381,124

(22) Filed: Jul. 20, 2021

(51) Int. Cl. G06F 7/556; G06F 5/01; G06N 3/08

(52) U.S. Cl. CPC G06F 7/556; G06F 5/01; G06N 3/08

(57) ABSTRACT

Apparatus and methods are disclosed for performing matrix operations, including operations suited to neural network and other machine learning accelerators and applications, using dual exponent formats. Disclosed matrix formats include single exponent bounding box floating-point (SE-BBFP) and dual exponent bounding box floating-point (DE-BBFP) formats. Shared exponents for each element are determined for each element based on whether the element is used as a row of matrix tile or a column of a matrix file, for example, for a dot product operation. Computing systems suitable for employing such neural networks include computers having general-purpose processors, neural network accelerators, or reconfigure both logic devices, such as Field programmable gate arrays (FPGA). Certain techniques disclosed herein can provide improved system performance while reducing memory and network bandwidth used.

### BACKGROUND

Machine learning (ML) and artificial intelligence (AI) techniques can be useful for solving a number of complex computational problems such as recognizing images and speech, analyzing and classifying information, and performing various classification tasks. Machine learning is a field of computer science that uses statistical techniques to give computer systems the ability to extract higher-level features from a set of training data. Specifically, the features can be extracted by training a model such as an artificial neural network (NN) or a deep neural network (DNN). After the model is trained, new data can be applied to the model and the new data can be classified (e.g., higher-level features can be extracted) using the trained model. Machine learning models are typically executed on a general-purpose processor (also referred to as a central processing unit (CPU)). However, training the models and/or using the models can be computationally expensive and so it may not be possible to perform feature extraction in real-time using general-purpose processors. Accordingly, there is ample opportunity for improvements in computer hardware and software to implement neural networks.

### SUMMARY

Apparatus and methods are disclosed for performing matrix operations, including operations suited to neural network and other machine learning accelerators and applications, using dual exponent formats. Disclosed matrix formats include single exponent bounding box floating-point (SE-BBFP) and dual exponent bounding box floating-point (DE-BBFP) formats. Shared exponents for each element are determined for each element based on whether the element is used as a row of matrix tile or a column of a matrix file, for example, for a dot product operation. Computing systems suitable for employing such neural networks include computers having general-purpose processors, neural network accelerators, or reconfigure both logic devices, such as Field programmable gate arrays (FPGA). Certain techniques disclosed herein can provide improved system performance while reducing memory and network bandwidth used.

In some examples of the disclosed technology, a computer system includes general-purpose and/or special-purpose neural network processors, and memory. As forward propagation occurs during training of neural network, activation values are produced in a first shared exponent format, SE-BBFP or DE-BBFP. The compressed activation values are stored in the bulk memory for use during backward propagation. When matrix values are stored in DE-BBFP format, the matrix can be used as a left or right operand for a matrix operation using a single set of significands.

In some examples of the disclosed technology, a computer-implemented method in includes using a processor to select a common exponent for a bounding box of elements of an input matrix to be stored in a dual exponent format, the common exponent being selected based on the smaller exponent for either a row or a column of the bounding box of elements, determine significands for the bounding box of elements of a dual exponent format matrix, each of the determined significands being selected by comparing a respective element's exponent to the common exponent, and store the determined significands and the common exponent as a dual exponent format matrix in a computer-readable storage medium.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

The foregoing and other objects, features, and advantages of the invention will become more apparent from the following detailed description, which proceeds with reference to the accompanying figures.

### BRIEF DESCRIPTION OF THE DRAWINGS

FIG. 1 is a bounding box diagram of a dual exponent-enabled system for performing training and inference using DE-BBFP format values, as can be implemented in certain examples of the disclosed technology.

FIG. 2 is a diagram depicting an example of a deep neural network, as can be modeled using certain example methods and apparatus disclosed herein.

FIG. 3 is a diagram depicting certain aspects of determining row exponents when converting a normal floating-point format to a DE-BBFP format, as can be performed in certain examples of the disclosed technology.

FIG. 4 is a diagram depicting certain aspects of determining column exponents when converting a normal floating-point format to a DE-BBFP format, as can be performed in certain examples of the disclosed technology.

FIG. 5 depicts an example of dual exponents and associated significands for a bounding box of matrix elements, as can be used in certain examples of the disclosed technology.

FIG. 6 depicts an example of dual exponents and associated significands for a bounding box of matrix elements, as can be used in certain examples of the disclosed technology.

FIG. 7 is a diagram of performing a matrix operation using DE-BBFP formats, as can be implemented in certain examples of the disclosed technology.

FIG. 8 is a diagram outlining a high-level architecture for performing tensor and matrix operations using DE-BBFP formatted data.

FIG. 9 is flow chart outfling an example of performing neural network training using DE-BBFP matrixes, as can be implemented in certain examples of the disclosed technology.

FIG. 10 is a flow chart illustrating an example of using DE-BBFP format matrices to perform matrix operations, as can be implemented in certain examples of the disclosed technology.

FIG. 11 is a flow chart depicting an example method of converting normal floating-point to DE-BBFP floating-point formats, as can be implemented in certain examples of the disclosed technology.

FIG. 12 is a flow chart depicting an example method of converting DE-BBFP floating-point format matrices to normal floating-point matrices, as can be implemented in certain examples of the disclosed technology.

FIG. 13 is a diagram illustrating a suitable computing environment for implementing some embodiments of the disclosed technology.

### DETAILED DESCRIPTION

### I. General Considerations

This disclosure is set forth in the context of representative embodiments that are not intended to be limiting in any way.

As used in this application the singular forms “a,” “an,” and “the” include the plural forms unless the context clearly dictates otherwise. Additionally, the term “includes” means “comprises.” Further, the term “coupled” encompasses mechanical, electrical, magnetic, optical, as well as other practical ways of coupling or linking items together, and does not exclude the presence of intermediate elements between the coupled items. Furthermore, as used herein, the term “and/or” means any one item or combination of items in the phrase.

The systems, methods, and apparatus described herein should not be construed as being limiting in any way. Instead, this disclosure is directed toward all novel and non-obvious features and aspects of the various disclosed embodiments, alone and in various combinations and subcombinations with one another. The disclosed systems, methods, and apparatus are not limited to any specific aspect or feature or combinations thereof, nor do the disclosed things and methods require that any one or more specific advantages be present or problems be solved. Furthermore, any features or aspects of the disclosed embodiments can be used in various combinations and subcombinations with one another.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed things and methods can be used in conjunction with other things and methods. Additionally, the description sometimes uses terms like “produce,” “generate,” “display,” “receive,” “verify,” “execute,” “perform,” “convert,” and “initiate” to describe the disclosed methods. These terms are high-level descriptions of the actual operations that are performed. The actual operations that correspond to these terms will vary depending on the particular implementation and are readily discernible by one of ordinary skill in the art.

Theories of operation, scientific principles, or other theoretical descriptions presented herein in reference to the apparatus or methods of this disclosure have been provided for the purposes of better understanding and are not intended to be limiting in scope. The apparatus and methods in the appended claims are not limited to those apparatus and methods that function in the manner described by such theories of operation.

Any of the disclosed methods can be implemented as computer-executable instructions stored on one or more computer-readable media (e.g., computer-readable media, such as one or more optical media discs, volatile memory components (such as DRAM or SRAM), or nonvolatile memory components (such as hard drives)) and executed on a computer (e.g., any commercially available computer, including smart phones or other mobile devices that include computing hardware). Any of the computer-executable instructions for implementing the disclosed techniques, as well as any data created and used during implementation of the disclosed embodiments, can be stored on one or more computer-readable media (e.g., computer-readable storage media). The computer-executable instructions can be part of, for example, a dedicated software application or a software application that is accessed or downloaded via a web browser or other software application (such as a remote computing application). Such software can be executed, for example, on a single local computer or in a network environment (e.g., via the Internet, a wide-area network, a local-area network, a client-server network (such as a cloud computing network), or other such network) using one or more network computers.

For clarity, only certain selected aspects of the software-based implementations are described. Other details that are well known in the art are omitted. For example, it should be understood that the disclosed technology is not limited to any specific computer language or program. For instance, the disclosed technology can be implemented by software written in C, C++, Java, or any other suitable programming language. Certain details of suitable computers and hardware are well-known and need not be set forth in detail in this disclosure.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, software applications, cable (including fiber optic cable), magnetic communications, electromagnetic communications (including RF, microwave, and infrared communications), electronic communications, or other such communication means.

### II. Overview of Artificial Neural Networks Using Dual Exponent Formats

Artificial Neural Networks (ANNs or as used throughout herein, “NNs”) are applied to a number of applications in Artificial Intelligence and Machine Learning including image recognition, speech recognition, search engines, and other suitable applications. The processing for these applications may take place on individual devices such as personal computers or cell phones, but it may also be performed in large datacenters. At the same time, hardware accelerators that can be used with NNs include specialized NN processing units, such as tensor processing units (TPUs) and Field Programmable Gate Arrays (FPGAs) programmed to accelerate neural network processing. Such hardware devices are being deployed in consumer devices as well as in data centers due to their flexible nature and low power consumption per unit computation.

Traditionally NNs have been trained and deployed using single-precision floating-point (32-bit floating-point or float32 format). However, it has been shown that lower precision floating-point formats, such as 16-bit floating-point (float16) or fixed-point formats can be used to perform inference operations with minimal loss in accuracy. On specialized hardware, such as FPGAs, reduced precision formats can greatly improve the latency and throughput of DNN processing.

Numbers represented in normal-precision floating-point format (e.g., a floating-point number expresses in a 16-bit floating-point format, a 32-bit floating-point format, a 64-bit floating-point format, or an 80-bit floating-point format) can be converted to DE-BBFP format numbers may allow for performance benefits in performing operations. In particular, NN weights and activation values can be represented in a lower-precision DE-BBFP format with an acceptable level of error introduced.

One of the characteristics of computation on an FPGA device is that it typically lacks hardware floating-point support. Floating-point operations may be performed at a penalty using the flexible logic, but often the amount of logic needed to support floating-point is prohibitive in FPGA implementations. Some newer FPGAs have been developed that do support floating-point computation, but even on these the same device can produce twice as many computational outputs per unit time as when it is used in an integer mode. Typically, NNs are created with floating-point computation in mind, but when an FPGA is targeted for NN processing it would be beneficial if the neural network could be expressed using integer arithmetic. Examples of the disclosed technology include hardware implementations of dual-exponent bounding box floating-point (DE-BBFP), including the use of DE-BBFP in NN, FPGA, and other hardware environments. As used herein, dual-exponent bound box floating-point refers to matrix representations where array elements can have two different exponents, depending on if the elements are being used in a matrix operation as a row or column of elements. In other words, each element uses a row exponent when the element is used on the left side of a matrix operation, and each element uses a column exponent, which can be different than the row exponent, when the element is used on the right side of a matrix operation. “Bounding box” or “bounding box” floating-point refers to cases where a group of elements in a matrix, but not necessarily all, share a common row or column exponent. For example, a 1024×1024 element matrix can be composed of 64×64 tiles, each of the tiles have 16×16 elements. Rows and columns in each tile share a common exponent.

A typical floating-point representation in a computer system consists of three parts: sign (s), exponent (e), and significand or significand (m). The sign indicates if the number is positive or negative. The exponent and significand are used as in scientific notation:

Value=s×m×2^{e} (Eq.1)

As used herein, “significand” refers to the significant digits of a number as expressed in scientific notation formats, including floating-point and bounding box floating box formats. A significand may often be referred to as a significand or coefficient. Any number may be represented, within the precision limits of the significand. Since the exponent scales the significand by powers of 2, just as the exponent does by powers of 10 in scientific notation, the magnitudes of very large numbers may be represented. The precision of the representation is determined by the precision of the significand. Typical floating-point representations use a significand of 10 (float 16), 24 (float 32), or 53 (float64) bits in width. An integer with magnitude greater than 2⁵³ can be approximated in a float64 floating-point format, but it will not be represented exactly because there are not enough bits in the significand. A similar effect can occur for arbitrary fractions where the fraction is represented by bits of the significand that take on the value of negative powers of 2. There are many fractions that cannot be exactly represented because they are irrational in a binary number system. More exact representations are possible in both situations, but they may require the significand to contain more bits. Ultimately, an infinite number of significand bits are required to represent some numbers exactly

$$( e . g . , \frac{1}{3} = 0 . \overline{3} ; \frac{22}{7} = 3. \overline{142857} ) .$$

The 10-bit (half precision float), 24-bit (single precision float), and 53-bit (double precision float) significand limits are common compromises of significand storage requirements versus representation precision in general-purpose computers.

With bounding box floating-point formats, a group of two or more numbers use a single shared exponent with each number still having its own sign and significand. In some examples, the shared exponent is chosen to be the largest exponent of the original floating-point values. For purposes of the present disclosure, the term bounding box floating-point (DE-BBFP) means a number system in which a single exponent is shared across two or more values, each of which is represented by a sign and significand pair (whether there is an explicit sign bit, or the significand itself is signed). In some examples, all values of one or more rows or columns of a matrix or vector, or all values of a matrix or vector, can share a common exponent. In other examples, the DE-BBFP representation may be unsigned. In some examples, some but not all of the elements in a matrix or vector DE-BBFP representation may include numbers represented as integers, floating-point numbers, fixed point numbers, symbols, or other data formats mixed with numbers represented with a sign, significand, and exponent. In some examples, some or all of the elements in a matrix or vector DE-BBFP representation can include complex elements having two or more parts, for example: complex numbers with an imaginary component (a+bi, where i=\sqrt{−1}); fractions including a numerator and denominator, in polar coordinates (r, θ), or other multi-component element.

Parameters of particular DE-BBFP formats can be selected for a particular implementation to tradeoff precision and storage requirements. For example, rather than storing an exponent with every floating-point number, a group of numbers can share the same exponent. To share exponents while maintaining a high level of accuracy, the numbers should have close to the same magnitude, since differences in magnitude are expressed in the significand. If the differences in magnitude are too great, the significand will overflow for the large values, or may be zero (“underflow”) for the smaller values. Depending on a particular application, some amount of overflow and/or underflow may be acceptable.

The size of the significand can be adjusted to fit a particular application. This can affect the precision of the number being represented, but potential gains are realized from a reduced representation size. For example, a normal single-precision float has a size of four bytes, but for certain implementations of the disclosed technology, only two bytes are used to represent the sign and significand of each value. In some implementations, the sign and significand of each value can be represented in a byte or less.

In certain examples of the disclosed technology, the representation expressed above is used to derive the original number from the representation, but only a single exponent is stored for a group of numbers, each of which is represented by a signed significand. Each signed significand can be represented by two bytes or less, so in comparison to four-byte floating-point, the memory storage savings is about 2×. Further, the memory bandwidth requirements of loading and storing these values are also approximately one-half that of normal floating-point.

Neural network operations are used in many artificial intelligence operations. Often, the bulk of the processing operations performed in implementing a neural network is in performing Matrix×Matrix or Matrix×Vector multiplications or convolution operations. Such operations are compute- and memory-bandwidth intensive, where the size of a matrix may be, for example, 1000×1000 elements (e.g., 1000×1000 numbers, each including a sign, significand, and exponent) or larger and there are many matrices used. As discussed herein, DE-BBFP techniques can be applied to such operations to reduce the demands for computation as well as memory bandwidth in a given system, whether it is an FPGA, CPU, or another hardware platform. As used herein, the use of the term “element” herein refers to a member of such a matrix or vector.

As used herein, the term “tensor” refers to a multi-dimensional array that can be used to represent properties of a NN and includes one-dimensional vectors as well as two-, three-, four-, or larger dimension matrices. As used in this disclosure, tensors do not require any other mathematical properties unless specifically stated.

As used herein, the term “normal-precision floating-point” or “regular floating-point” refers to a floating-point number format where each number has a significand, an exponent, and optionally a sign and which is natively supported by a native or virtual CPU. Examples of normal-precision floating-point formats include, but are not limited to, IEEE 754 standard formats such as 16-bit, 32-bit, 64-bit, or to other processors supported by a processor, such as Intel AVX, AVX2, IA32, x86_64, or 80-bit floating-point formats.

A given number can be represented using different precision formats. For example, a number can be represented in a higher precision format (e.g., float32) and a lower precision format (e.g., float16). Lowering the precision of a number can include reducing the number of bits used to represent the significand or exponent of the number. Additionally, lowering the precision of a number can include reducing the range of values that can be used to represent an exponent of the number, such as when multiple numbers share a common exponent. Similarly, increasing the precision of a number can include increasing the number of bits used to represent the significand or exponent of the number. Additionally, increasing the precision of a number can include increasing the range of values that can be used to represent an exponent of the number, such as when a number is separated from a group of numbers that shared a common exponent.

The term “quantized dual exponent floating-point” or “quantized DE-BBFP” refers to dual exponent floating-point number formats where two or more values of a tensor have been modified to have a lower precision than when the values are represented in normal-precision floating-point. For example, after converting matrix values to a dual-exponent format, 16-bit significands can be quantized to any number of fewer bits, including 8, 7, 4, or 3 bits, to further reduce storage and processing hardware requirements. Dual exponent 8-bit significands can be converted to any number of fewer bits, including 7, 4, or 3 bits. Quantization is particularly useful in certain neural network processing applications during training and other operations where the loss of precision can be tolerated with similar results in the deployed neural network.

In one example of the disclosed technology, a neural network accelerator is configured to performing training operations for layers of a neural network, including forward propagation and back propagation. The values of one or more of the neural network layers can be expressed in a DE-BBFP or quantized DE-BBFP (QDE-BBFP) formats. For example, DE-BBFP formats can be used to accelerate computations performed in training and inference operations using the neural network accelerator. Use of dual exponent formats can improve neural network processing by, for example, allowing for faster hardware, reduced memory overhead, simpler hardware design, reduced energy use, reduced integrated circuit area, cost savings and other technological improvements. When it is not known whether a matrix will be used as a left operand or a right operand for a matrix operation, or a matrix will be used as both a left operand and a right operand, using DE-BBFP format allows the matrix values to be stored using a single set of significands, a set of column exponents, and a set of row exponents. In contrast, a SE-BBFP format matrix, where it is unknown whether the matrix will be used as a left operand or a right operand, or as both a left and right operand, requires two sets of significands, each set shifted relative to its exponent, and two sets of exponents be stored. Thus, use of dual format matrices as described herein offers substantial savings of memory, computation, and interconnect resources.

It is often desirable that operations be performed to mitigate noise or other inaccuracies introduced by using lower-precision formats. Further, portions of neural network training, such as temporary storage of activation values, can be improved by compressing a portion of these values (e.g., for an input, hidden, or output layer of a neural network), either from normal-precision floating-point or from a DE-BBFP, to a lower precision DE-BBFP format. The activation values can be later retrieved for use during, for example, back propagation during the training phase.

An input tensor for the given layer can be converted from a normal-precision floating-point format to a DE-BBFP floating-point format. A tensor operation can be performed using the converted input tensor. A result of the tensor operation can be converted from the DE-BBFP format to the normal-precision floating-point format. The tensor operation can be performed during a forward-propagation mode or a back-propagation mode of the neural network. For example, during a back-propagation mode, the input tensor can be an output error term from a layer adjacent to (e.g., following) the given layer or weights of the given layer. As another example, during a forward-propagation mode, the input tensor can be an output term from a layer adjacent to (e.g., preceding) the given layer or weights of the given layer. The converted result can be used to generate an output tensor of the layer of the neural network, where the output tensor is in normal-precision floating-point format. In this manner, the neural network accelerator can potentially be made smaller and more efficient than a comparable accelerator that uses only a normal-precision floating-point format. A smaller and more efficient accelerator may have increased computational performance and/or increased energy efficiency. By increasing the accuracy of the accelerator, a convergence time for training may be decreased and the accelerator may be more accurate when classifying inputs to the neural network. Reducing the computational complexity of using the models can potentially decrease the time to extract a feature during inference, decrease the time for adjustment during training, and/or reduce energy consumption during training and/or inference.

On certain chips dedicated to machine learning/deep learning (ML/DL) processing three expensive hardware components are arithmetic processing units, on-chip memories, and data fabrics that move weights and activation data between processing units. Significant portion of computing is matrix multiplications. DE-BBFP representations can be used to reduce the hardware complexity of matrix multiplication units. Typically, the data is stored in some floating-point/integer form and then converted to DE-BBFP at the time of computation to reduce computing hardware.

DE-BBFP representations of data provide an efficient way for storing data in applications using DE-BBFP arithmetic. The DE-BBFP can be converted (on the fly) to single-exponent bounding box floating-point (SE-BBFP) format prior to computation. Conversion from DE-BBFP to SE-BBFP is easy and nearly lossless. The data can be converted from floating-point or integer format to DE-BBFP format and stored at once. In some examples, DE-BBFP representations require 40-70% less storage compared to storing data in 16-bit or 32-bit regular floating-point formats. Data storage using DE-BBFP formats may also reduce data fabric bandwidth needed to move data both on-chip and off-chip by similar percentages.

### III. Example Architectures for Implementing

Activation Compression with DE-BBFP Formats

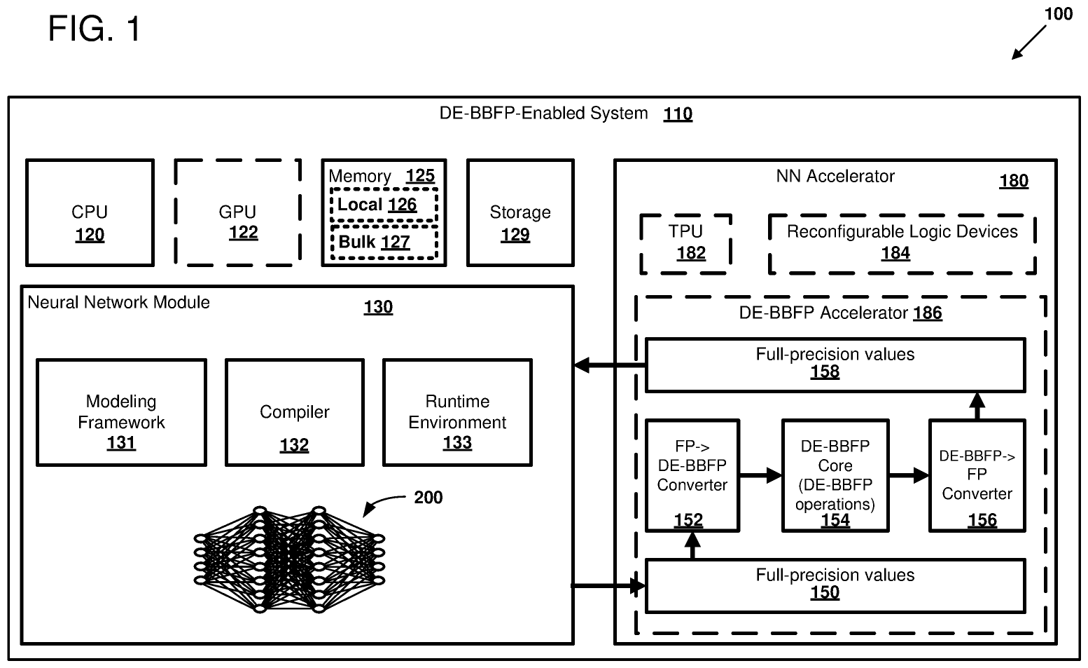

FIG. 1 is a bounding box diagram 100 outlining an example dual exponent-enabled system 110 as can be implemented in certain examples of the disclosed technology, including for use in activation compression with DE-BBFP. As shown in FIG. 1, the dual exponent-enabled system 110 can include a number of hardware resources including general-purpose processors 120 and special-purpose processors such as graphics processing units 122 and neural network accelerator 180. The processors are coupled to memory 125 and storage 129, which can include volatile or non-volatile memory devices. The processors 120 and 122 execute instructions stored in the memory or storage in order to provide a neural network module 130. The neural network module 130 includes software interfaces that allow the system to be programmed to implement various types of neural networks. For example, software functions can be provided that allow applications to define neural networks including weights, biases, activation functions, node values, and interconnections between layers of a neural network. Additionally, software functions can be used to define state elements for recurrent neural networks. The neural network module 130 can further provide utilities to allow for training and retraining of a neural network implemented with the module. Values representing the neural network module are stored in memory or storage and are operated on by instructions executed by one of the processors. The values stored in memory or storage can be represented using normal-precision floating-point, SE-BBFP, DE-BBFP, or QDE-BBFP format floating-point values.

In some examples, proprietary or open source libraries or frameworks are provided to a programmer to implement neural network creation, training, and evaluation. Examples of such libraries include TensorFlow, Microsoft Cognitive Toolkit (CNTK), Caffe, Theano, and Keras. In some examples, programming tools such as integrated development environments provide support for programmers and users to define, compile, and evaluate NNs.

The neural network accelerator 180 can be implemented as a custom or application-specific integrated circuit (e.g., including a system-on-chip (SoC) integrated circuit), as a field programmable gate array (FPGA) or other reconfigurable logic, or as a soft processor virtual machine hosted by a physical, general-purpose processor. The neural network accelerator 180 can include a tensor processing unit 182, reconfigurable logic devices 184, and/or one or more neural processing cores (such as the DE-BBFP accelerator 186). The DE-BBFP accelerator 186 can be configured in hardware, software, or a combination of hardware and software. As one example, the DE-BBFP accelerator 186 can be configured and/or executed using instructions executable on the tensor processing unit 182. As another example, the DE-BBFP accelerator 186 can be configured by programming reconfigurable logic devices 184. As another example, the DE-BBFP accelerator 186 can be configured using hard-wired logic gates of the neural network accelerator 180.

The DE-BBFP accelerator 186 can be programmed to execute a subgraph, an individual layer, or a plurality of layers of a neural network. For example, the DE-BBFP accelerator 186 can be programmed to perform operations for all or a portion of a layer of a NN. The DE-BBFP accelerator 186 can access a local memory used for storing weights, biases, input values, output values, forget values, state values, and so forth. The DE-BBFP accelerator 186 can have many inputs, where each input can be weighted by a different weight value. For example, the DE-BBFP accelerator 186 can produce a dot product of an input tensor and the programmed input weights for the DE-BBFP accelerator 186. In some examples, the dot product can be adjusted by a bias value before it is used as an input to an activation function. The output of the DE-BBFP accelerator 186 can be stored in the local memory, where the output value can be accessed and sent to a different NN processor core and/or to the neural network module 130 or the memory 125, for example. Intermediate values in the DE-BBFP can often be stored in a smaller or more local memory, while values that may not be needed until later in a training process can be stored in a “bulk memory” a larger, less local memory (or storage device, such as on an SSD (solid state drive) or hard drive). For example, during training forward propagation, once activation values for a next layer in the NN have been calculated, those values may not be accessed until for propagation through all layers has completed. Such activation values can be stored in such a bulk memory.

The neural network accelerator 180 can include a plurality 110 of DE-BBFPs 186 that are connected to each other via an interconnect (not shown). The interconnect can carry data and control signals between individual DE-BBFP accelerator(s) 186, a memory interface (not shown), and an input/output (I/O) interface (not shown). The interconnect can transmit and receive signals using electrical, optical, magnetic, or other suitable communication technology and can provide communication connections arranged according to a number of different topologies, depending on a particular desired configuration. For example, the interconnect can have a crossbar, a bus, a point-to-point bus, or other suitable topology. In some examples, any one of the plurality of DE-BBFP accelerators 186 can be connected to any of the other cores, while in other examples, some cores are only connected to a subset of the other cores. For example, each core may only be connected to a nearest 4, 8, or 10 neighboring cores. The interconnect can be used to transmit input/output data to and from the DE-BBFP accelerator 186, as well as transmit control signals and other information signals to and from the DE-BBFP accelerator 186. For example, each of the DE-BBFP accelerators 186 can receive and transmit semaphores that indicate the execution status of operations currently being performed by each of the respective DE-BBFP accelerators 186. Further, matrix and vector values can be shared between DE-BBFP accelerators 186 via the interconnect. In some examples, the interconnect is implemented as wires connecting the DE-BBFP accelerators 186 and memory system, while in other examples, the core interconnect can include circuitry for multiplexing data signals on the interconnect wire(s), switch and/or routing components, including active signal drivers and repeaters, or other suitable circuitry. In some examples of the disclosed technology, signals transmitted within and to/from neural network accelerator 180 are not limited to full swing electrical digital signals, but the neural network accelerator 180 can be configured to include differential signals, pulsed signals, or other suitable signals for transmitting data and control signals.

In some examples, the DE-BBFP-enabled system 110 can include an optional DE-BBFP emulator that emulates functions of the neural network accelerator 180. The neural network accelerator 180 provides functionality that can be used to convert data represented in full precision floating-point formats in the neural network module 130 into DE-BBFP format values. In some examples, the neural network accelerator 180 may perform operations using quantized DE-BBFP format values. Such functionality will be discussed in further detail below.

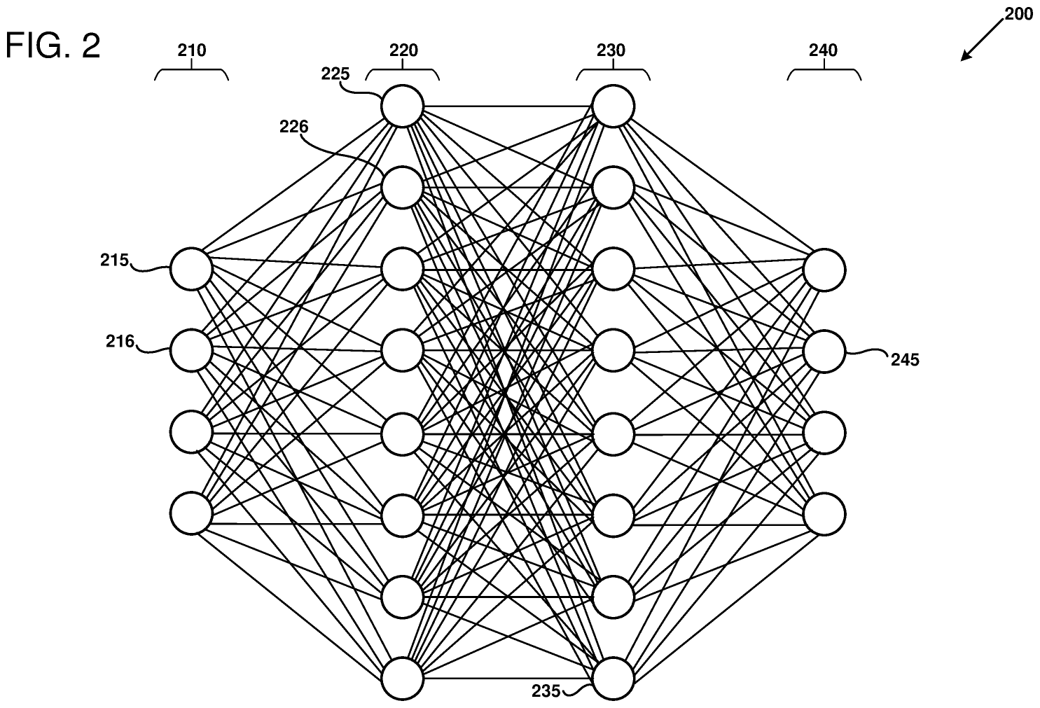

The neural network module 130 can be used to specify, train, and evaluate a neural network model using a tool flow that includes a hardware-agnostic modelling framework 131 (also referred to as a native framework or a machine learning execution engine), a neural network compiler 132, and a neural network runtime environment 133. The memory includes computer-executable instructions for the tool flow including the modelling framework 131, the neural network compiler 132, and the neural network runtime environment 133. The tool flow can be used to generate neural network data 200 representing all or a portion of the neural network model, such as the neural network model discussed below regarding FIG. 2. It should be noted that while the tool flow is described as having three separate tools (131, 132, and 133), the tool flow can have fewer or more tools in various examples. For example, the functions of the different tools (131, 132, and 133) can be combined into a single modelling and execution environment. In other examples, where a neural network accelerator is deployed, such a modeling framework may not be included.

The neural network data 200 can be stored in the memory 125, which can include local memory 126, which is typically implemented as static read only memory (SRAM), embedded dynamic random access memory (eDRAM), in latches or flip-flops in a register file, in a bounding box RAM, or other suitable structure, and bulk memory 127, which is typically implemented in memory structures supporting larger, but often slower access than the local memory 126. For example, the bulk memory may be off-chip DRAM, network accessible RAM, SSD drives, hard drives, or network-accessible storage. Depending on a particular memory technology available, other memory structures, including the foregoing structures recited for the local memory, may be used to implement bulk memory. The neural network data 200 can be represented in one or more formats. For example, the neural network data 200 corresponding to a given neural network model can have a different format associated with each respective tool of the tool flow. Generally, the neural network data 200 can include a description of nodes, edges, groupings, weights, biases, activation functions, and/or tensor values. As a specific example, the neural network data 200 can include source code, executable code, metadata, configuration data, data structures and/or files for representing the neural network model.

The modelling framework 131 can be used to define and use a neural network model. As one example, the modelling framework 131 can include pre-defined APIs and/or programming primitives that can be used to specify one or more aspects of the neural network model. The pre-defined APIs can include both lower-level APIs (e.g., activation functions, cost or error functions, nodes, edges, and tensors) and higher-level APIs (e.g., layers, convolutional neural networks, recurrent neural networks, linear classifiers, and so forth). “Source code” can be used as an input to the modelling framework 131 to define a topology of the graph of a given neural network model. In particular, APIs of the modelling framework 131 can be instantiated and interconnected within the source code to specify a complex neural network model. A data scientist can create different neural network models by using different APIs, different numbers of APIs, and interconnecting the APIs in different ways.

In addition to the source code, the memory 125 can also store training data. The training data includes a set of input data for applying to the neural network model 200 and a desired output from the neural network model for each respective dataset of the input data. The modelling framework 131 can be used to train the neural network model with the training data. An output of the training is the weights and biases that are associated with each node of the neural network model. After the neural network model is trained, the modelling framework 131 can be used to classify new data that is applied to the trained neural network model. Specifically, the trained neural network model uses the weights and biases obtained from training to perform classification and recognition tasks on data that has not been used to train the neural network model. The modelling framework 131 can use the CPU 120 and the special-purpose processors (e.g., the GPU 122 and/or the neural network accelerator 180) to execute the neural network model with increased performance as compare with using only the CPU 120. In some examples, the performance can potentially achieve real-time performance for some classification tasks.

The compiler 132 analyzes the source code and data (e.g., the examples used to train the model) provided for a neural network model and transforms the model into a format that can be accelerated on the neural network accelerator 180, which will be described in further detail below. Specifically, the compiler 132 transforms the source code into executable code, metadata, configuration data, and/or data structures for representing the neural network model and memory as neural network data 200. In some examples, the compiler 132 can divide the neural network model into portions (e.g., neural network 200) using the CPU 120 and/or the GPU 122) and other portions (e.g., a subgraph, an individual layer, or a plurality of layers of a neural network) that can be executed on the neural network accelerator 180. The compiler 132 can generate executable code (e.g., runtime modules) for executing NNs assigned to the CPU 120 and for communicating with a subgraph, an individual layer, or a plurality of layers of a neural network assigned to the accelerator 180. The compiler 132 can generate configuration data for the accelerator 180 that is used to configure accelerator resources to evaluate the subgraphs assigned to the optional accelerator 180. The compiler 132 can create data structures for storing values generated by the neural network model during execution and/or training and for communication between the CPU 120 and the accelerator 180. The compiler 132 can generate metadata that can be used to identify subgraphs, edge groupings, training data, and various other information about the neural network model during runtime. For example, the metadata can include information for interfacing between the different subgraphs or other portions of the neural network model.

The runtime environment 133 provides an executable environment or an interpreter that can be used to train the neural network model during a training mode and that can be used to evaluate the neural network model in training, inference, or classification modes. During the inference mode, input data can be applied to the neural network model inputs and the input data can be classified in accordance with the training of the neural network model. The input data can be archived data or real-time data.

The runtime environment 133 can include a deployment tool that, during a deployment mode, can be used to deploy or install all or a portion of the neural network to neural network accelerator 180. The runtime environment 133 can further include a scheduler that manages the execution of the different runtime modules and the communication between the runtime modules and the neural network accelerator 180. Thus, the runtime environment 133 can be used to control the flow of data between nodes modeled on the neural network module 130 and the neural network accelerator 180.

In one example, the neural network accelerator 180 receives and returns normal-precision values 150 from the neural network module 130. As illustrated in FIG. 1, the DE-BBFP accelerator 186 can perform a bulk of its operations using DE-BBFP format floating-point and an interface between the DE-BBFP accelerator 186 and the neural network module 130 can use full-precision values for communicating information between the modules. The normal-precision values can be represented in 16-, 32-, 64-bit, or other suitable floating-point format. For example, a portion of values representing the neural network can be received, including edge weights, activation values, or other suitable parameters for processing using dual exponent format(s). The normal-precision values 150 are provided to a normal-precision floating-point to DE-BBFP converter 152, which converts the normal-precision value into dual exponent format values. Dual exponent floating-point operations 154 can then be performed

on the converted values. Suitable hardware for implementing the DE-BBFP processing unit 154 include general-purpose processors, neural network accelerators, or reconfigure both logic devices, such as Field Programmable Gate Arrays (FPGA). In addition, intermediate values can be stored in memory (e.g., memory 135, storage 139, or other volatile or non-volatile memory in communication with or within the accelerator 186) for SE-BBFP or DE-BBFP arrays produced by the accelerator 186. Thus, successive matrix operations can be performed in dual exponent formats. After a one or more matrix operations, the dual exponent format values can then be converted back to a normal-floating-point format using a DE-BBFP to normal-floating-point converter 156 which produces normal-precision floating-point values. As a specific example, the DE-BBFP accelerator 186 can be used to accelerate a given layer of a neural network, and the vector-vector, matrix-vector, matrix-matrix, and convolution operations can be performed using SE-BBFP and DE-BBFP format floating-point operations and less compute-intensive operations (such as adding a bias value or calculating an activation function) can be performed using normal floating-point precision operations. In some examples, the DE-BBFP formats can be further quantized (e.g., by reducing the precision of the exponents and/or significands of the DE-BBFP elements to a few number of bits by truncating or rounding values to a lower number of bits).

The conversions between normal floating-point and DE-BBFP performed by the converters 152 and 156 are typically performed on sets of numbers represented as vectors or multi-dimensional matrices. In some examples, additional normal-precision operations 158, including operations that may be desirable in particular neural network implementations can be performed based on normal-precision formats including adding a bias to one or more nodes of a neural network, applying a hyperbolic tangent function or other such sigmoid function, or rectification functions (e.g., ReLU operations) to normal-precision values that are converted back from the DE-BBFP format.

In some examples, the dual exponent values are used and stored only in the logic gates and internal memories of the neural network accelerator 180, and the memory 125 and storage 129 store only normal floating-point values. For example, the neural network accelerator 180 can convert the inputs, weights, and activations for a neural network model that are received from the neural network model 130 to DE-BBFP and can convert back to normal floating-point the results of the operations that are performed on the neural network accelerator 180 before passing the values back to the neural network model 130. Values can be passed between the neural network model 130 and the neural network accelerator 180 using the memory 125, the storage 129, or an input/output interface (not shown). In other examples, an emulator provides full emulation of the DE-BBFP accelerator, including only storing one copy of the shared exponent and operating with reduced significand widths. Some results may differ over versions where the underlying operations are performed in normal floating-point. For example, certain examples can check for underflow or overflow conditions for a limited, quantized bit width (e.g., 3-, 4-, or 5-bit wide significands).

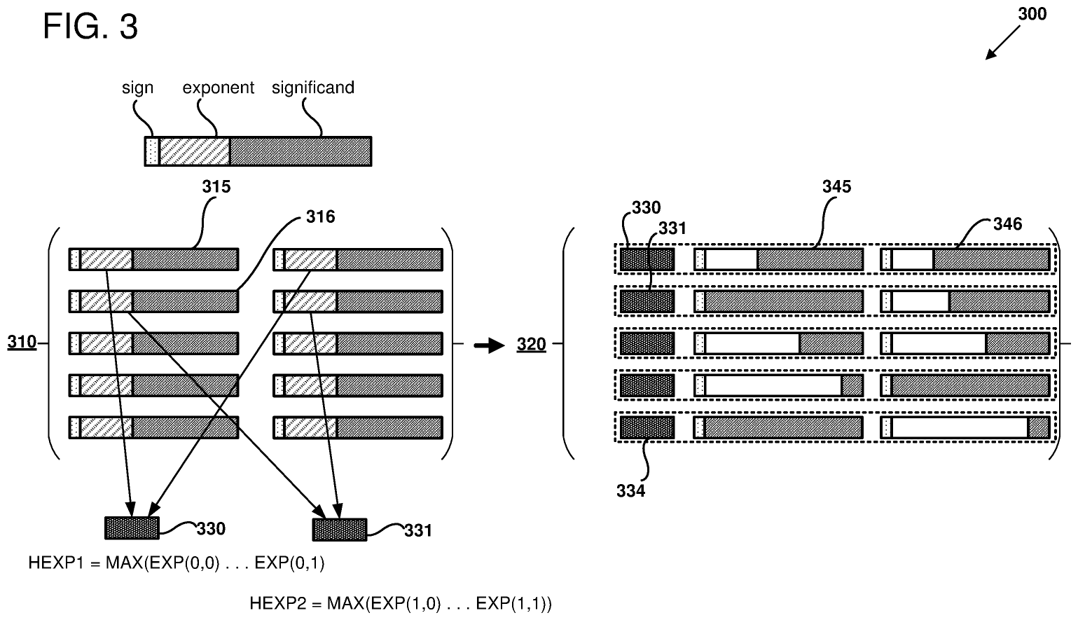

The bulk of the computational cost of DNNs is in vector-vector, matrix-vector, and matrix-matrix multiplications and/or convolutions. These operations are quadratic in input sizes while operations such as bias add and activation functions are linear in input size. Thus, in some examples, DE-BBFP formats are only used for matrix-vector multiplication operations, which is implemented on the neural network accelerator 180. In such examples, all other operations are done in a normal-precision format, such as float16. Thus, from the user or programmer's perspective, the DE-BBFP-enabled system 110 accepts and outputs normal-precision float16 values from/to the neural network module 130 and output float16 format values. All conversions to and from bounding box floating-point format can be hidden from the programmer or user. In some examples, the programmer or user may specify certain parameters for DE-BBFP operations. In other examples, DE-BBFP operations can take advantage of bounding box floating-point format to reduce computation complexity, as discussed below regarding FIG. 3.

The neural network accelerator 180 is used to accelerate evaluation and/or training of a neural network graph or subgraphs, typically with increased speed and reduced latency that is not realized when evaluating the subgraph using only the CPU 120 and/or the GPU 122. In the illustrated example, the accelerator includes a Tensor Processing Unit (TPU) 182, reconfigurable logic devices 184 (e.g., contained in one or more FPGAs or a programmable circuit fabric), and/or a DE-BBFP accelerator 186, however any suitable hardware accelerator can be used that models neural networks. The accelerator 180 can include configuration logic which provides a soft CPU. The soft CPU supervises operation of the accelerated graph or subgraph on the accelerator 180 and can manage communications with the neural network module 130. The soft CPU can also be used to configure logic and to control loading and storing of data from RAM on the accelerator, for example in bounding box RAM within an FPGA.

In some examples, parameters of the neural network accelerator 180 can be programmable. The neural network accelerator 180 can be used to prototype training, inference, or classification of all or a portion of the neural network model 200. For example, DE-BBFP parameters can be selected based on accuracy or performance results obtained by prototyping the network within neural network accelerator 180. After a desired set of DE-BBFP parameters is selected, a model can be programmed into the accelerator 180 for performing further operations.

The compiler 132 and the runtime 133 provide a fast interface between the neural network module 130 and the neural network accelerator 180. In effect, the user of the neural network model may be unaware that a portion of the model is being accelerated on the provided accelerator. For example, node values are typically propagated in a model by writing tensor values to a data structure including an identifier. The runtime 133 associates subgraph identifiers with the accelerator, and provides logic for translating the message to the accelerator, transparently writing values for weights, biases, and/or tensors to the neural network accelerator 180 without program intervention. Similarly, values that are output by the neural network accelerator 180 may be transparently sent back to the neural network module 130 with a message including an identifier of a receiving node at the server and a payload that includes values such as weights, biases, and/or tensors that are sent back to the overall neural network model.

FIG. 2 illustrates a simplified topology of a deep neural network (DNN) 200 that can be used to perform enhanced image processing using disclosed DE-BBFP implementations. One or more processing layers can be implemented using disclosed techniques for SE-BBFP and DE-BBFP matrix/vector operations, including the use of one or more of a plurality of neural network DE-BBFPs 186 in the DE-BBFP-enabled system 110 described above. It should be noted that applications of the neural network implementations disclosed herein are not limited to DNNs but can also be used with other types of neural networks, such as convolutional neural networks (CNNs), including implementations having Long Short Term Memory (LSTMs) or gated recurrent units (GRUs), or other suitable artificial neural networks that can be adapted to use DE-BBFP methods and apparatus disclosed herein.

The DNN 200 can operate in at least two different modes. Initially, the DNN 200 can be trained in a training mode and then used as a classifier in an inference mode. During the training mode, a set of training data can be applied to inputs of the DNN 200 and various parameters of the DNN 200 can be adjusted so that at the completion of training, the DNN 200 can be used as a classifier. Training includes performing forward propagation of the training input data, calculating a loss (e.g., determining a difference between an output of the DNN and the expected outputs of the DNN), and performing backward propagation through the DNN to adjust parameters (e.g., weights and biases) of the DNN 200. When an architecture of the DNN 200 is appropriate for classifying the training data, the parameters of the DNN 200 will converge and the training can complete. After training, the DNN 200 can be used in the inference mode. Specifically, training or non-training data can be applied to the inputs of the DNN 200 and forward propagated through the DNN 200 so that the input data can be classified by the DNN 200.

As shown in FIG. 2, a first set 210 of nodes (including nodes 215 and 216) form an input layer. Each node of the set 210 is connected to each node in a first hidden layer formed from a second set 220 of nodes (including nodes 225 and 226). A second hidden layer is formed from a third set 230 of nodes, including node 235. An output layer is formed from a fourth set 240 of nodes (including node 245). In example 200, the nodes of a given layer are fully interconnected to the nodes of its neighboring layer(s). In other words, a layer can include nodes that have common inputs with the other nodes of the layer and/or provide outputs to common destinations of the other nodes of the layer. In other examples, a layer can include nodes that have a subset of common inputs with the other nodes of the layer and/or provide outputs to a subset of common destinations of the other nodes of the layer.

During forward propagation, each of the nodes produces an output by applying a weight to each input generated from the preceding node and collecting the weights to produce an output value. In some examples, each individual node can have an activation function (σ) and/or a bias (b) applied. Generally, an appropriately programmed processor or FPGA can be configured to implement the nodes in the depicted neural network 200. In some example neural networks, an output function ƒ(n) of a hidden combinational node n can produce an output expressed mathematically as:

$$f ( n ) = σ ( {\sum }_{i = 0 to E - 1} {w}_{i} {x}_{i} + b ) \qquad ( Eq . 2 )$$

where wᵢ is a weight that is applied (multiplied) to an input edge xᵢ, b is a bias value for the node n, σ is the activation function of the node n, and E is the number of input edges of the node n. In some examples, the activation function produces a continuous value (represented as a floating-point number) between 0 and 1. In some examples, the activation function produces a binary 1 or 0 value, depending on whether the summation is above or below a threshold.

A given neural network can include thousands of individual nodes and so performing all of the calculations for the nodes in normal-precision floating-point can be computationally expensive. An implementation for a more computationally expensive solution can include hardware that is larger and consumes more energy than an implementation for a less computationally expensive solution. However, performing the operations using DE-BBFP floating-point can potentially reduce the computational complexity of the neural network. In some cases, a simple implementation that uses only DE-BBFP floating-point may significantly reduce the computational complexity, but the implementation may have difficulty converging during training and/or correctly classifying input data because of errors introduced by the DE-BBFP. However, dual exponent floating-point implementations disclosed herein can potentially increase an accuracy of some calculations while also providing the benefits of reduced complexity associated with dual exponent floating-point formats.

The DNN 200 can include nodes that perform operations in with DE-BBFP floating-point. As a specific example, an output function ƒ(n) of a hidden combinational node n can produce an output expressed mathematically as:

$$f ( n ) = σ {\sum }_{i = 0 to E - 1} DE ( {w}_{i} ) DE ( {x}_{i} ) + b \qquad ( Eq . 3 )$$

where wᵢ is a weight that is applied (multiplied) to an input edge xᵢ, DE(wᵢ) is the DE-BBFP format value of the weight, DE(xᵢ) is the DE-BBFP format value of the input sourced from the input edge xᵢ, b is a bias value for the node n, σ is the activation function of the node n, and E is the number of input edges of the node n. The computational complexity can potentially be reduced (as compared with using only normal-precision floating-point values) by performing the dot product using floating-point values, and the accuracy of the output function can potentially be increased by the other operations of the output function using normal-precision floating-point values.

Neural networks can be trained and retrained by adjusting constituent values of the output function ƒ(n). For example, by adjusting weights wᵢ or bias values b for a node, the behavior of the neural network is adjusted by corresponding changes in the networks output tensor values. For example, a cost function C(w, b) can be used during back propagation to find suitable weights and biases for the network, where the cost function can be described mathematically as:

$$C ( w , b ) = \frac{1}{2 n} {\sum }_{χ} {‖ y ( x ) - a ‖}^{2} \qquad ( Eq . 4 )$$

where w and b represent all weights and biases, n is the number of training inputs, a is a vector of output values from the network for an input vector of training inputs x. By adjusting the network weights and biases, the cost function C can be driven to a goal value (e.g., to zero (0)) using various search techniques, for examples, stochastic gradient descent. The neural network is said to converge when the cost function C is driven to the goal value. Similar to the output function ƒ(n), the cost function can be implemented using dual exponent computer arithmetic. For example, the vector operations can be performed using DE-BBFP values and operations, and the non-vector operations can be performed using normal-precision floating-point values.

Examples of suitable applications for such neural network DE-BBFP implementations include, but are not limited to: performing image recognition, performing speech recognition, classifying images, translating speech to text and/or to other languages, facial or other biometric recognition, natural language processing, automated language translation, query processing in search engines, automatic content selection, analyzing email and other electronic documents, relationship management, biomedical informatics, identifying candidate biomolecules, providing recommendations, or other classification and artificial intelligence tasks.

A network accelerator (such as the network accelerator 180 in FIG. 1) can be used to accelerate the computations of the DNN 200. As one example, the DNN 200 can be partitioned into different subgraphs or network layers that can be individually accelerated. As a specific example, each of the layers 210, 220, 230, and 240 can be a subgraph or layer that is accelerated, with the same or with different accelerators. The computationally expensive calculations of the layer can be performed using DE-BBFP formats and the less expensive calculations of the layer can be performed using normal-precision floating-point. Values can be passed from one layer to another layer using normal-precision floating-point. By accelerating a group of computations for all nodes within a layer, some of the computations can be reused and the computations performed by the layer can be reduced compared to accelerating individual nodes.

In some examples, a set of parallel multiply-accumulate (MAC) units in each convolutional layer can be used to speed up the computation. Also, parallel multiplier units can be used in the fully-connected and dense-matrix multiplication stages. A parallel set of classifiers can also be used. Such parallelization methods have the potential to speed up the computation even further at the cost of added control complexity.

As will be readily understood to one of ordinary skill in the art having the benefit of the present disclosure, the application of neural network implementations can be used for different aspects of using neural networks, whether alone or in combination or subcombination with one another. For example, disclosed implementations can be used to implement neural network training via gradient descent and/or back propagation operations for a neural network. Further, disclosed implementations can be used for evaluation of neural networks.

### IV. Example Conversions and Uses of SE-BBFP and DE-BBFP Format Matrices

FIG. 3 is a diagram 300 illustrating an example of determining row exponents when converting a normal floating-point format to a DE-BBFP format, as can be implemented in certain examples of the disclosed technology. For example, input tensors for a neural network represented as normal floating-point numbers (for example, in a 32-bit or 16-bit floating-point format) can be converted to the illustrated bounding box floating-point format.

As shown, a matrix of normal floating-point format numbers 310 are represented such that each number, for example number 315 or number 316 include a sign, an exponent, and a significand. For example, for IEEE 754 half precision floating-point format, the sign is represented using one bit, the exponent is represented using 5 bits, and the significand is represented using 10 bits. When the floating-point format numbers 310 in the neural network model 200 are converted to a set of DE-BBFP format numbers, there is one exponent value that is shared by all of the numbers in a particular row of the illustrated groups. Thus, as shown, the set of SE-BBFP numbers 320 share a single exponent value (330, 331, 334, etc.) for each row, while each of the set of numbers includes a sign and a significand. However, since the illustrated set of numbers have different exponent values in the floating-point format, each number's respective significand may be shifted such that the same or a proximate number is represented in the SE-BBFP format (e.g., shifted significands 345 and 346). The illustrated matrix has 5 rows and 2 columns, although typically matrices used for disclosed applications have the same number of rows and columns (e.g., 8×8, 16×16, etc.).

The shared row exponent 330 (HEXP1) for the first row of the matrix 310 is calculated as the maximum of the exponent values in the first row: HEXP1=MAX(EXP(0,0) . . . EXP(0,1). The shared row exponent 331 (HEXP2) for the second row of the matrix 310 is calculated as the maximum of the exponent values in the second row: HEXP2=MAX(EXP(1,0) . . . EXP(1,1)). The remaining three row exponents are calculated in a similar fashion.

In some examples, the shared row exponents 330-334 are selected to be the largest exponent from among the original normal-precision numbers in the neural network model 200. In other examples, the shared row exponents may be selected in a different manner, for example, by selecting an exponent that is a mean or median of the normal floating-point exponents in a particular row, or by selecting an exponent to maximize dynamic range of values stored in the significands when their numbers are converted to the SE-BBFP/DE-BBFP number format. It should be noted that some bits of the shifted significands may be lost if the shared exponent and the value's original floating-point exponent are not the same. This occurs because the significand is shifted to correspond to the new, shared exponent.

There are several possible choices for which values in a bounding box floating-point tensor will share an exponent. The simplest choice is for all values in a row or column of a matrix or a matrix tile (e.g., a 16×16 tile) to share an exponent. However, sharing an exponent over a finer granularity can reduce errors because it increases the likelihood of DE-BBFP numbers using a shared exponent that is closer to their original normal floating-point format exponent. Thus, loss of precision due to dropping significand bits (when shifting the significand to correspond to a shared exponent) can be reduced.

In some examples, the computational cost of matrix-vector multiplication can be further reduced by reducing significand widths. A large range of values having a shared common exponent can be expressed with only a few bits of significand. for example, in a representation with 4 bits of significand and a 5-bit exponent, values can be expressed in a range [2⁻¹⁴0.001₂, 2¹⁵1.111₂], or approximately [2⁻¹⁷, 2¹⁶]. in contrast, a 4-bit fixed point number can only represent values in the range [0001₂, 1111₂], or approximately [2⁰, 2⁴].

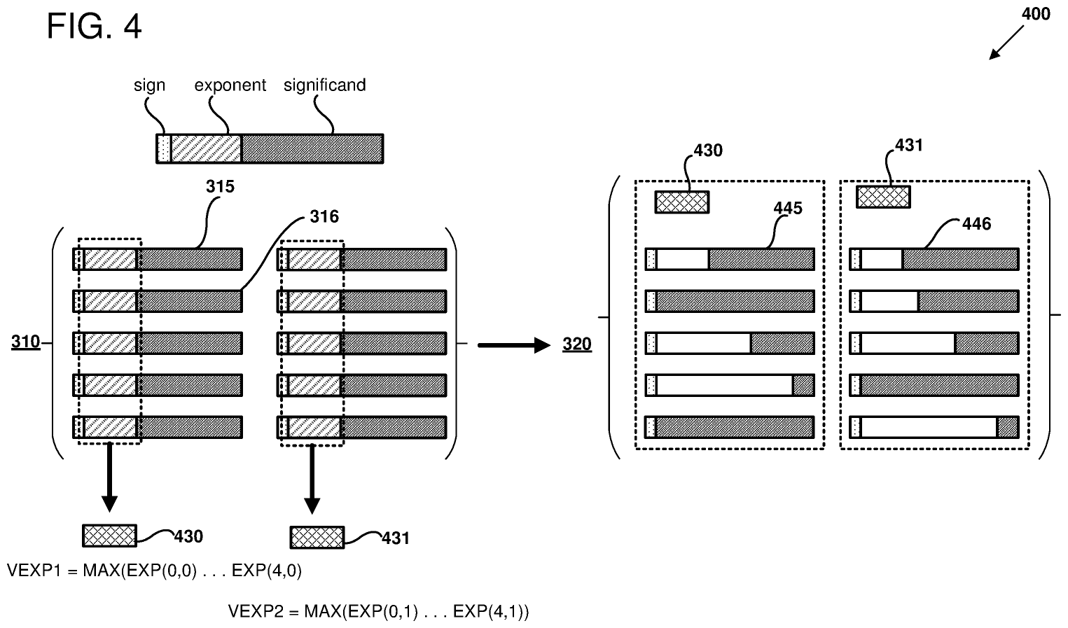

FIG. 4 is a diagram 400 illustrating an example of determining column exponents when converting a normal floating-point format to a DE-BBFP format, as can be implemented in certain examples of the disclosed technology. For example, input tensors for a neural network represented as normal floating-point numbers (for example, in a 32-bit or 16-bit floating-point format) can be converted to the illustrated bounding box floating-point format.

As shown, the normal floating-point format numbers 310 discussed above regarding FIG. 3 are represented such that each number, for example number 315 or number 316, includes a sign, an exponent, and a significand. When the floating-point format numbers 310 in the neural network model 200 are converted to a set of DE-BBFP format numbers, there is one exponent value that is shared by all of the numbers in a particular column of the illustrated groups. Thus, as shown, the set of SE-BBFP numbers 320 share a single exponent value (430 and 431) for each column, while each of the set of numbers includes a sign and a significand. However, since the illustrated set of numbers have different exponent values in the floating-point format, each number's respective significand may be shifted such that the same or a proximate number is represented in the SE-BBFP format (e.g., shifted significands 445 and 446). As will be discussed in further detail below, when the conversion to DE-BBFP is complete, the shifting of the significands is determined by the maximum of each element's row and column exponents.

The shared row exponent 430 (VEXP1) for the first row of the matrix 310 is calculated as the maximum of the exponent values in the first row: VEXP1=MAX(EXP(0,0) . . . EXP(4,0). The shared row exponent 331 (VEXP2) for the second row of the matrix 310 is calculated as the maximum of the exponent values in the second row: VEXP2=MAX(EXP(0,1) . . . EXP(4,1)). There are only two columns in this example for ease of explanation, but additional column shared exponent would be calculated in a similar fashion.

In some examples, the shared column exponents 430 and 431 are selected to be the largest exponent from among the original normal-precision numbers in the neural network model 200. In other examples, the shared row exponents may be selected in a different manner, for example, by selecting an exponent that is a mean or median of the normal floating-point exponents in a particular row, or by selecting an exponent to maximize dynamic range of values stored in the significands when their numbers are converted to the SE-BBFP/DE-BBFP number format. It should be noted that some bits of the shifted significands may be lost if the shared exponent and the value's original floating-point exponent are not the same. This occurs because the significand is shifted to correspond to the new, shared exponent.

There are several possible choices for which values in a bounding box floating-point tensor will share an exponent. The simplest choice is for all values in a row or column of a matrix or a matrix tile (e.g., a 16×16 tile) to share an exponent. However, sharing an exponent over a finer granularity can reduce errors because it increases the likelihood of DE-BBFP numbers using a shared exponent that is closer to their original normal floating-point format exponent. Thus, loss of precision due to dropping significand bits (when shifting the significand to correspond to a shared exponent) can be reduced.

In block based floating-point matrix multiplication applications where a matrix can be used either as the left operand or as a right operand, using DE-BBFP representations allows storing the matrix data efficiently in a compact way. In such a case significands for each matrix element in this representation is computed as follows:

Consider a simple 2×2 array (shown with decimal values) as shown below. For ease of explanation, the sign of the elements is ignored.

$$\vert \begin{matrix}4 & 256 \\ 8 & 64\end{matrix} \vert$$

In floating-point format, the exponents for each element are:

$$\vert \begin{matrix}129 & 135 \\ 130 & 133\end{matrix} \vert$$

Thus, the significands in matrix form are therefore:

$$\vert \begin{matrix}0 & 0 \\ 0 & 0\end{matrix} \vert$$

It should be noted the significands here are all zeroes due to the implied leading ‘1’ value.

To store the matrix in an 8-bit SE-BBFP format along rows, the maximum exponent in each row is determined to be [135, 133]. A single exponent representation of Matrix (along horizontal): would be common exponent array of [135, 133] and so the the significand matrix is:

$$\vert \begin{matrix}( 128 ≫ ( 135 - 129 ) & ( 128 ≫ ( 135 - 135 ) ) \\ ( 128 ≫ ( 133 - 130 ) & ( 128 ≫ ( 133 - 133 ) )\end{matrix} \vert$$

which can be simplified as the following hexadecimal values:

$$\vert \begin{matrix}0 x 02 & 0 x 80 \\ 0 x 10 & 0 x 80\end{matrix} \vert$$

Similarly, to store the matrix using SE-BBFP along columns, the vertical exponents are [130, 135], and the single exponent representation of Matrix (along vertical) is:

$$\vert \begin{matrix}( 128 ≫ ( 130 - 129 ) ) & ( 128 ≫ ( 135 - 135 ) \\ ( 128 ≫ ( 130 - 130 ) ) & ( 128 ≫ ( 135 - 133 ) )\end{matrix} \vert$$

which can be simplified as the following hexadecimal values:

$$⌈ \begin{matrix}0 x 40 & 0 x 80 \\ 0 x 80 & 0 x 20\end{matrix} ⌉$$

It should be noted that the accuracy of the resulting matrices are different. It depends on the direction of block-floating-point (whether it is along rows or whether it is along columns) and correlation between the elements in that direction.

To convert the SE-BBFP representation back to FP32, the normalized significand is computed using LS (number of left shifts) for each element as below:

$$\vert \begin{matrix}1 & 0 \\ 0 & 2\end{matrix} \vert$$

The significand after stripping the most significand bit and shifting is:

$$\vert \begin{matrix}0 & 0 \\ 0 & 0\end{matrix} \vert$$

And the corresponding exponents are:

$$\vert \begin{matrix}129 ( = 130 - 1 ) & 135 \\ 130 & 131 = ( 135 - 2 )\end{matrix} \vert$$

For dual exponent format, DE-BBFP, let Sᵣ(i,j) be the significand for (i, j)^{th} element of the matrix for single exponent BBFP along rows. This is how the matrix will be stored if it is going to be used as left operand of matrix multiplication operation.

Let S_{c}(i,j) be the significand for (i, j)^{th} element of the matrix for single exponent BBFP along columns. This is how the matrix will be stored if the matrix is going to be used as right operand of matrix multiplication operation.

Then, the DE-BBFP significand, S_{de}(i, j), can be expressed as:

S_{de}(i,j)=max{Sᵣ(i,j),S_{c}(i,j)}

The sign of each element in DE_BBFP will be same as the sign of corresponding element in either of SE_BBFP matrices. It should be noted that S_{de}(i, j) being larger of the two significands, retains the accuracy of the more accurate significand.

Conceptually, the following C language data structure can be used to store a DE-BBFP tile with 8-bit precision significands:

```
struct DE_BBFP_1_8_TILE
{
  UINT8 _hexp[16];
  UINT8 _vexp[16];
  BOOL _sign[16][16];
  UINT8 _significand[16][16];
};
```

A 16×16 tile with elements expressed in a 16-bit floating-point format bfloat16 requires 512 bytes of storage. In one example, a single exponent (SE-BBFP) tile will use 16 bytes for its shared exponents, 256 bytes for significands, and 32 bytes (256 bits) for the signs, for a total of 304 bytes. In one examples, a dual exponent (DE-BBFP) tile will use 32 bytes for shared exponents (vectors HEXP and VEXP), 256 bytes for significands, and 32 bytes (256 bits) for the sign values. Thus, the total storage requirement for a DE-BBFP format in this example is 320 bytes, which is about 62.5% of the storage occupied by the tile in bfloat16 format.

In the example above, the DE-BBFP significand is obtained as below from the two SE-BBFP representations.

$$Max \{ \vert \begin{matrix}0 x 02 & 0 x 80 \\ 0 x 10 & 0 x 80\end{matrix} \vert , \vert \begin{matrix}0 x 40 & 0 x 80 \\ 0 x 80 & 0 x 20\end{matrix} \vert \} \to \vert \begin{matrix}0 x 40 & 0 x 80 \\ 0 x 80 & 0 x 80\end{matrix} \vert$$

### V. Example DE-BBFP Tile Hardware

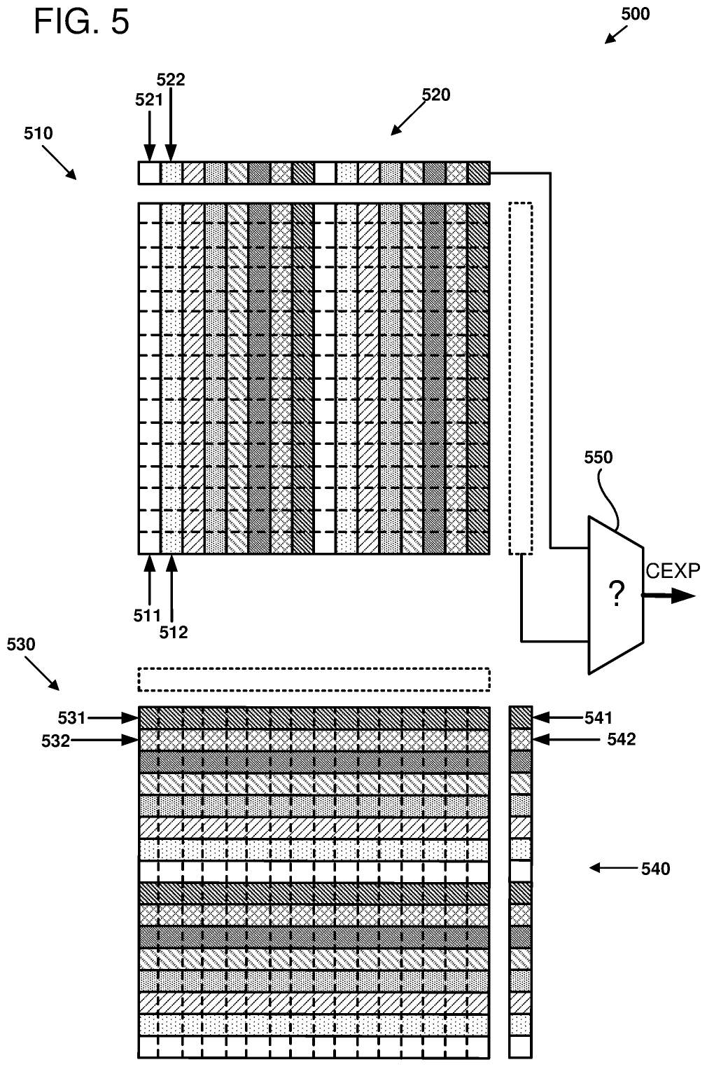

FIG. 5 is a block diagram 500 depicting a high-level hardware architecture for storing and using DE-BBFP matrices, as can be implemented in certain examples of the disclosed technology. For example, the DE-BBFP enabled system 110 discussed above can be used to accelerate matrix operations for machine learning applications.

As shown, a memory includes a 16×16 element array, or tile. In this example, there are a number of columns, for example the first column 511 and a second column 512. The maximum value of the exponent for the 16 elements in each respective column 511, 512 is determined, and the maximum exponent is stored in the common column an exponent register 520. A first common exponent 521 corresponds to the column 511 of elements, and a second common exponent 522 corresponds to a second column of elements.

The same memory is depicted at 530, this time showing groupings by row for the same memory 510. As shown, a first row 531 of 16 values is evaluated to find the maximum value, and the maximum exponent 541 is stored in a common row exponent register 540. Similarly, a second column 532 of 16 values is evaluated to find its maximum value, and stored at 542 in the common row exponent register 540.

When using the DE-BBFP matrix to perform major operations, the maximum or minimum common exponent CEXP for each element can be found using a comparator normal 550. The comparator 550 output can be used to shift significands for each of the elements stored in the memory 510.

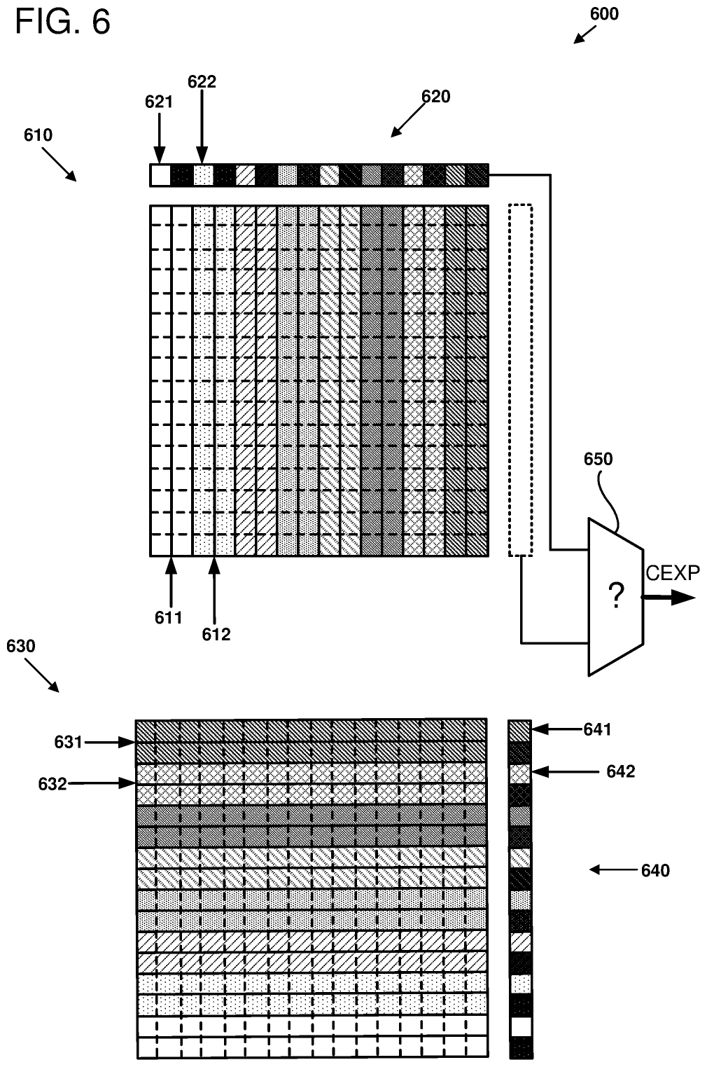

FIG. 6 is a block diagram 500 depicting an alternative example of a high-level hardware architecture for storing and using DE-BBFP matrices, as can be implemented in certain examples of the disclosed technology. For example, the DE-BBFP enabled system 110 discussed above can be used to accelerate matrix operations for machine learning applications.

Similar to the example of FIG. 6, the hardware includes a memory storing a 16×16 element array, or tile. In this example, however, each bounding box includes two columns. For example, a first two columns 611 are a first bounding box and a second pair of columns 612 is assigned as a second bounding box. The maximum value of the exponent for the 32 elements in each pair of respective columns 611, 612 is determined, and the maximum exponent is stored in an exponent register 620. A first common exponent 621 corresponds to the first two columns 611 of elements, and a second common exponent 622 corresponds to a second column of elements 612.

The same memory is depicted at 630, this time showing groupings by rows for the same memory 610. As shown, a first pair of rows 631 of 32 values is evaluated to find the maximum value, and the maximum exponent 641 is stored in a common row exponent register 640. Similarly, a second pair of rows 632 of 32 values is evaluated to find its maximum value, and stored at 642 in the common row exponent register 640.

When using the DE-BBFP matrix to perform major operations, the maximum or minimum common exponent CEXP for each element can be found using a comparator normal 650. The comparator 650 output can be used to shift significands for each of the elements stored in the memory 610.

### VI. Example Methods of Matrix Operations Using SE-BBFP and DE-BBFP Matrices

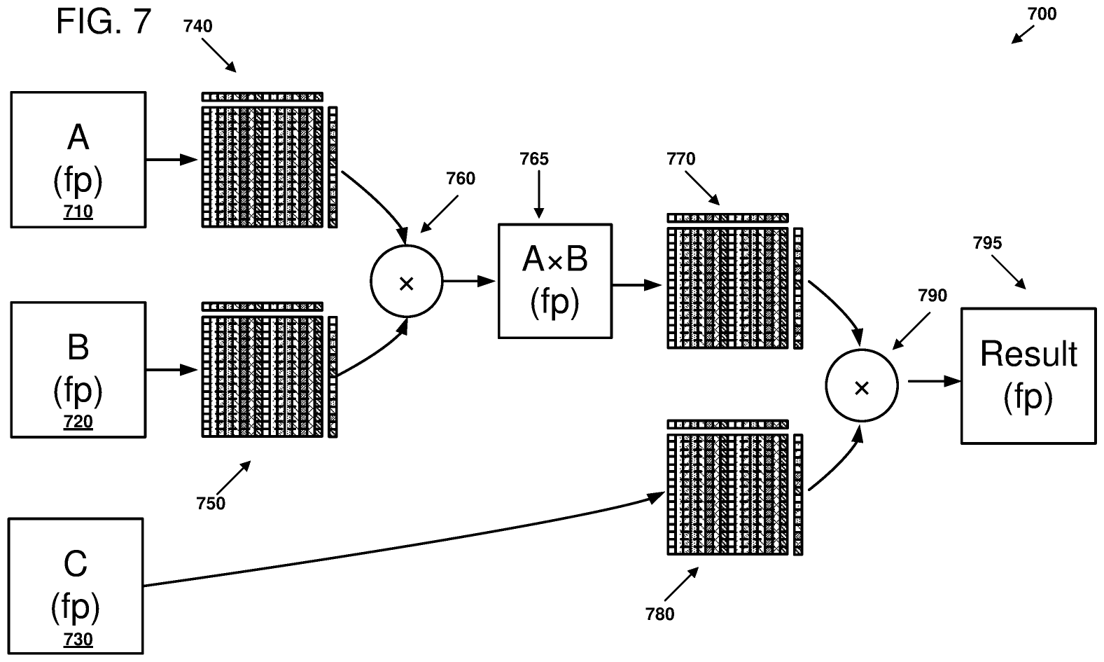

FIG. 7 is a block diagram 700 outlining an example of using SE-BBFP and DE-BBFP matrices performing matrix operations, as can be implement it in certain examples of the disclosed technology. For example, the DE-BBFP enabled system 110 discussed above can be used to implement the described operations.

As shown, there are 3 tiles A, B, and C of 16×16 normal floating-point values stored in memory at 710, 720, and 730. The first matrix operation to be performed is a matrix multiply of A×B. Each floating-point matrix is converted to DE-BBFP format. The A matrix if converted to a DE-BBFP format matrix 740 and stored in memory or streamed; similarly, the B matrix is converted to a DE-BBFP format matrix 750.

One or more tensor operations are performed using BBFP processing unit 760. Because the A matrix will be the left operand, it is converted from DE-BBFP so that it has common row exponents stored in SE-BBFP format in a memory 740 as shown. The B matrix will be the right operand, so it is converted from DE-BBFP so that it has common column exponents stored in SE-BBFP format in the memory 750. The 2 matrices A and B are multiplied and the result is stored in a memory 765 in normal floating-pointformat. The floating-point matrix stored in the memory 765 can then be converted to DE-BBFP format for storage or subsequent tensor operations.

In other examples, Because it is known that the A×B result will be the left operand for another matrix multiply, the result is converted to an SE-BBFP format having common row exponents. If the use of the results is not known, the result would be converted to DE-BBFP format, in the appropriate row or column exponents can be used at a later time. The input C matrix in memory 730 is converted to DE-BBFP format 780 having common column exponents. One or more tensor operations are performed using BBFP processing unit 760. Here, the result of the 2^{nd} matrix multiply, (A×B)×C, is used as normal floating-point format and stored in memory 795. In some examples, because the C matrix is the right operand for the matrix multiply, it is converted directly to SE-BBFP instead of DE-BBFP. In some examples, one or more of the tiles A, B, or C may be directly converted to SE-BBFP prior to being used for the matrix operation. In some examples, the BBFP processing unit 790 is the same as unit as the BBFP processing unit 760; while in other examples, distinct processing units are employed.

It will be readily understood to one of ordinary skill in the art having the benefit of the present disclosure that additional operations can be performed with matrices stored in SE-BBFP and DE-BBFP formats, in the results converted at a later time to a normal floating-point format. Further, any of the SE-BBFP matrices can also be stored as DE-BBFP format matrices.

### VII. Example Dual Exponent Matrix Processing Architecture

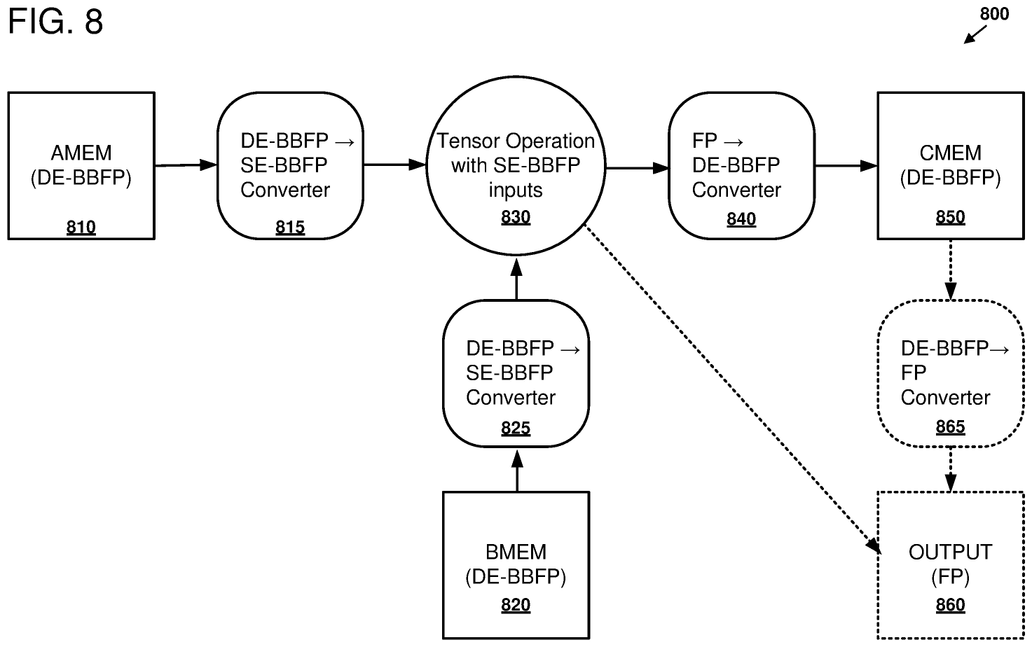

FIG. 8 is a block diagram outlining a dual exponent matrix processing architecture, as can be implemented in certain examples of the disclosed technology. For example, the DE-BBFP-enabled system 110 can implement the DE-BBFP processing unit 154 using the architecture shown in FIG. 8. Suitable hardware for implementing the DE-BBFP processing unit 154 include general-purpose processors, neural network accelerators, or reconfigure both logic devices, such as Field programmable gate arrays (FPGA). In some examples, the DE-BBFP processing unit 154 includes dedicated circuitry, including exponent registers, memory, shifters, arithmetic units, logic units, etc. for performing disclosed DE-BBFP operations.

As shown in FIG. 8, a first memory AMEM 810 is storing data for a DE-BBFP matrix that has received or converted from another format (e.g., converted from normal floating-point). Prior to being used for matrix/tensor operations, a converter 815 converts the DE-BBFP data to an SE-BBFP format compatible with the operation to be performed. If the AMEM matrix will be used as a left matrix operand, then the matrix is converted to SE-BBFP having common row exponents; conversely, if used as a right matrix operand, the matrix is converted to SE-BBFP having common column exponents. Depending on whether a give row or column exponent is larger, the significand is either shifted or maintained. For example, if the row exponents are being used and the row exponent is larger or equal to the column exponent, then the associated significand is not shifted. On the other hand, if the row exponent is smaller than the column exponent, then the significands are shifted accordingly. The SE-BBFP matrix produced by the converter 815 may be stored in a temporary memory or buffer, or streamed directly to be used in a tensor operation performed using BBFP processing unit 830.

A second memory BMEM 820 stores data for a DE-BBFP matrix in a similar fashion as the AMEM matrix 810. The values are converted to SE-BBFP values prior to consumption for a tensor operation 830, in a similar way as converter 815, depending on whether the BMEM values are used as left or right operands.

The BBFP processing unit 830 performs one or more matrix operations using the SE-BBFP matrices produced by converters 815, 825. Any suitable matrix operation can be performed using the DE-BBFP matrix (as converted to SE-BBFP). For example, matrix multiplication, as well as addition, subtraction, computing inverse matrices, or determinants can be performed. Suitable hardware for implementing the BBFP processing unit 830 include general-purpose processors, neural network accelerators, or reconfigure both logic devices, such as Field programmable gate arrays (FPGA). In some examples, the DE-BBFP processing unit 154 includes dedicated circuitry, including exponent registers, memory, shifters, arithmetic units, logic units, etc. for performing disclosed DE-BBFP operations.

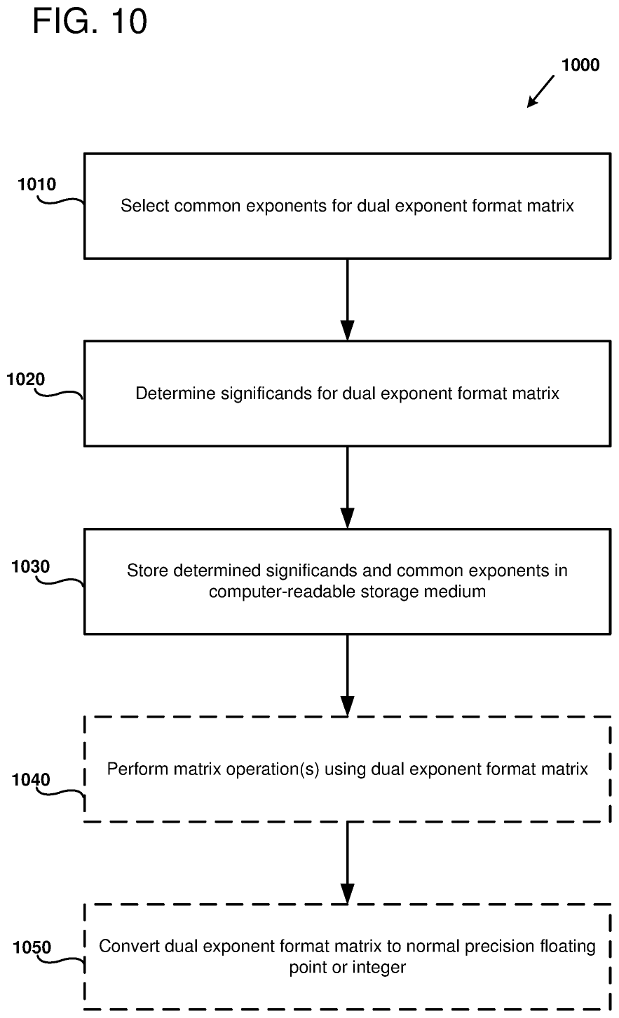

The output of the DE-BBFP operations will be in a normal floating-point format, as every output element will have a new significand and exponent produced by the BBFP processing unit. The floating-point output can be converted to DE-BBFP using similar techniques, for example, as process blocks 1010, 1020, and 1030 described above regarding FIG. 10. The converted DE-BBFP result (CMEM) is stored in a memory 850. Subsequently, CMEM can be used for additional matrix operations by converting to SE-BBFP and using as a left or right operand for tensor operations.

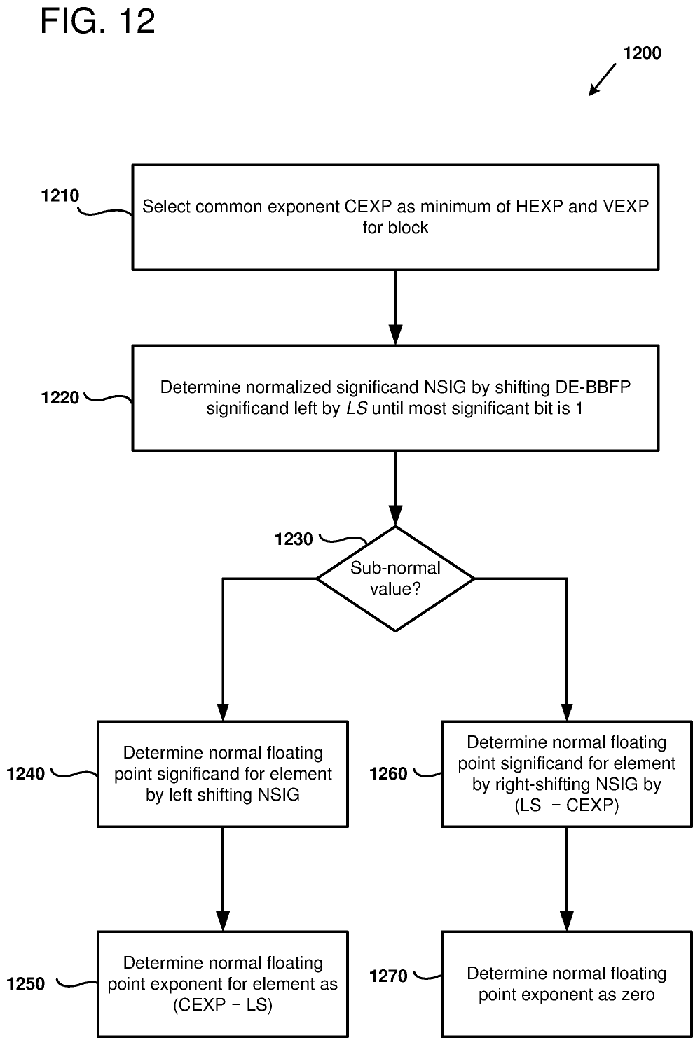

At some point, the result data can be converted to a normal floating-point format for use with hardware configured to operate in the normal floating-point domain. For example, floating-point output can be stored in a memory 860 in normal floating-point format. In some examples, the output is converted to fixed point or integer format. The floating-point output can be produced by DE-BBFP to FP converter 865. For example, the operations described below regarding FIG. 12 can be used to perform conversion to normal floating-point format. Suitable hardware for implementing the DE-BBFP to FP converter 865 includes general-purpose processors, neural network accelerators, or reconfigure both logic devices, such as Field programmable gate arrays (FPGA).

In other examples, the normal floating-point output is not generated with the converter 865, but uses the output of the tensor operation produced by the BBFP processing unit 830. In some examples, further conversion is performed. For example, in some cases, the tensor operation output may have 8-bit significands and 5-bit exponents, and be padded or shifted to be properly formatted in the desired floating-point output format. For example, bfloat16 has 8-bit precision significands and exponents, while float32 format has 24-bit precision significands and 8-bit exponents. In addition, special cases (e.g, NaN, underflow/overflow, subnormal or other special cases) may have different representations in the target floating-point output format.

### VIII. Example Methods of Neural Network Training

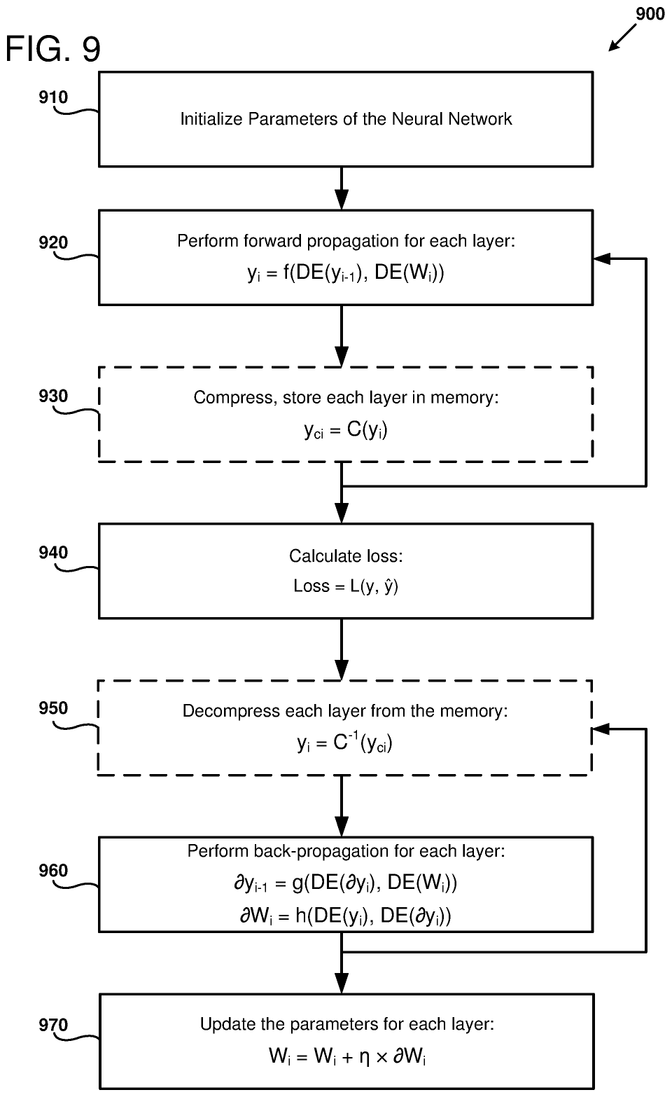

FIG. 9 is a flow diagram depicting a method 900 of training a neural network using a model with a DE-BBFP format, as can be implemented in certain examples of the disclosed technology. For example, training the neural network can include iterating through a set of training data, where the method 900 is used for updating the parameters of the neural network during a given iteration of training data. As one example, the method 900 can be performed by a DE-BBFP-enabled system, such as the DE-BBFP-enabled system 110 of FIG. 1.

At process block 910, parameters, such as weights and biases, of the neural network can be initialized. As one example, the weights and biases can be initialized to random normal-precision floating-point values. As another example, the weights and biases can be initialized to normal-precision floating-point values that were calculated from an earlier training set. The initial parameters can be stored in a memory or storage of the DE-BBFP-enabled system. In one example, the parameters can be stored as DE-BBFP values which can reduce an amount storage used for storing the initial parameters.

At process block 920, input values of the neural network can be forward propagated through the neural network. Input values of a given layer of the neural network can be an output of another layer of the neural network. The values can be passed between the layers from an output of one layer to an input of the next layer using normal-precision floating-point. The output function of the layer i can include a term that is described mathematically as:

yᵢ=ƒ(DE(yᵢ₋₁),DE(Wᵢ)) (Eq. 5)

where yᵢ₋₁ is the output from a layer providing the input to layer i, Wᵢ is the weight tensor for the layer i, ƒ( ) is a forward function of the layer, and DE( ) is a conversion to DE-BBFP function. The output function of the layer can be the floating-point value produced by DE-BBFP operations represented as ƒ( ) or alternatively, the output function can include additional terms, such as an activation function or the addition of a bias, that are performed using normal-precision floating-point (before conversion to DE-BBFP) or using DE-BBFP floating-point (after conversion to DE-BBFP). Generally, the inputs, outputs, and parameters of the layers are tensors. Typically, the inputs, outputs, and parameters of the layers will be vectors or matrices. The DE-BBFP conversion function converts normal-precision floating-point values to DE-BBFP values. The specific DE-BBFP format can be selected to account for the type of input data and the types of operations performed by the layer i. For example, when yᵢ and Wᵢ are two-dimensional matrices and the output function includes a term that takes the cross product of yᵢ₋₁ and Wᵢ, the function for yᵢ₋₁ can use a bounding box including a row or a portion of a row of yᵢ₋₁, and the function for Wᵢ can use a bounding box including a column or a portion of a column of Wᵢ. The computation can be more efficient when selecting the bounding boxes to follow the flow of the operators, thus making a hardware implementation smaller, faster, and more energy efficient.

At process block 930, a portion of a neural network, such as a layer that was just forward propagated to the next layer of the neural network can be compressed and stored in memory. For example, activation values calculated as part of forward propagation as discussed above process block 920 can be compressed and stored in the memory. This compression can be expressed mathematically as:

y_{ci}=C(yᵢ) (Eq. 6)

where yᵢ are the values generated by forward propagation for a layer at process block 920, C( ) is an optional, additional compression function (which may include multiple compression operations) and y_{ci} are compressed values to be stored in memory. In other examples, no compression operations are performed, and so operation described at process block 930 are not performed. In such a case, it follows that decompression operations as described regarding process block 950, below, are unnecessary and will not be performed.

In some examples, an additional quantization function can further compress the DE-BBFP values to a smaller quantized format than used in the DE-BBFP layer. In such cases, the compressed activation values are expressed in a second DE-BBFP format that can differ from a first DE-BBFP used to perform forward propagation calculations and at least one of the following ways: having a different significand format or having a different exponent format. For example, if forward propagation was performed using activation significand values expressed in a 9-bit format, these values can be transformed to a 4-bit format by truncating or rounding the significand. As another example, activation value exponents, including shared exponents in DE-BBFP format can be transformed from a 7-bit format to a 5-bit format. Values can be translated between the formats used by any suitable technique. For example, truncation or rounding of exponents, along with any significand shifting performed to compensate for adjusted exponents can be performed. In some examples, table lookups or other techniques can be used to perform the translation.

In some examples, additional compression can be applied to the compressed bounding box floating-point format prior to storing in memory. Examples of suitable techniques for further compressing activation values in the compressed format include entropy compression (e.g., Huffman encoding), zero compression, run length compression, compressed sparse row compression, or compressed sparse column compression.

At process block 940, a loss of the neural network can be calculated. For example, the output y of the neural network can be compared to an expected output ŷ of the neural network. A difference between the output and the expected output can be an input to a cost function that is used to update the parameters of the neural network.

At process block 950, activation values stored in memory are decompressed for back propagation, and in particular, for calculation of output error terms used in backpropagation for a particular layer. The method can iterate over each layer and decompress activation values for each layer, perform backpropagation for the layer, and then decompress activation values for the preceding layer. This decompression can be expressed mathematically as:

yᵢ=C⁻¹(y_{ci}) (Eq. 7)

where y_{ci} are the compressed values retrieved from memory and C⁻¹( ) is an optional decompression function (which may include multiple compression operations) that is inverse of the optional compression function C( ), and yᵢ are the values generated by forward propagation for a layer at process block 920. For example, after forward propagation is completed for every layer and a neural network as discussed above regarding process blocks 920 and 930, and losses calculated as discussed above at process block 940, values are back propagated back through the neural network, typically starting from the output layer of the neural network. Further, if additional compression was applied prior to storing in memory, such as entropy compression, zero compression, run length encoding, compressed sparse row compression, or compressed sparse column compression, these operations can be reversed prior to performing back propagation for a layer at process block 960.

At process block 960, the loss of the neural network can be back-propagated through the neural network. During back propagation, an output error term ∂_{y} and a weight error term ∂W can be calculated. The output error term can be described mathematically as:

∂yᵢ₋₁=g(DE(∂yᵢ),DE(Wᵢ)) (Eq. 9)

where ∂yᵢ₋₁ is the output error term from a layer following layer i, Wᵢ is the weight tensor for the layer i, g( ) is a backward function of the layer, and DE( ) is a dual exponent conversion function. The backward function g( ) can be can be the backward function of ƒ( ) for a gradient with respect to yᵢ₋₁ or a portion of the gradient function.

The weight error term ∂W can be described mathematically as:

∂Wᵢ=h(DE(yᵢ),DE(∂yᵢ)) (Eq. 9)

where ∂Wᵢ is the weight error term for the layer i, ∂yᵢ is the output error term for the layer i, yᵢ is the output for the layer i, h( ) is a backward function of the layer, and DE( ) is a dual exponent format function. The backward function h( ) can be can be the backward function of ƒ( ) for a gradient with respect to Wᵢ₋₁ or a portion of the weight error equation 9. The weight error term can include additional terms that are performed using normal-precision floating-point.

At process block 970, the parameters for each layer can be updated. For example, the weights for each layer can be updated by calculating new weights based on the iteration of training. As one example, a weight update function can be described mathematically as:

Wᵢ=Wᵢ+η×∂Wᵢ (Eq. 10)

where ∂Wᵢ is the weight error term for the layer i, η is the learning rate for the layer i for the neural network, Wᵢ is the weight tensor for the layer i. In one example, the weight update function can be performed using normal-precision floating-point.

### IX. High-Level Description of Generating and Using DE-BBFP Matrix Operations

FIG. 10 is a flowchart 1000 outlining an example method of converting a normal floating-point matrix to a DE-BBFP matrix and using the matrix in matrix operations. The DE-BBFP enabled system 110 discussed above regarding FIG. 1 is an example of a system that can be used to perform the illustrated method. For example, neural network operations as discussed above at FIGS. 2 and 8, including the use of number formats described above regarding FIG. 3 can be used to implement the illustrated method. As will be readily understood to a person of ordinary skill in the art having the benefit of the present disclosure, different variations of DE-BBFP systems and dual exponent formats can be adapted to perform the illustrated method.

At process block 1010, the maximum row exponents (HEXP) and column exponents (VEXP) for each row and column in a normal floating-point format input matrix are determined. Thus, for an N×M input matrix, having significands m_{i,j}, exponents e_{i,j}, and sign bits s_{i,j}, HEXP will be a vector of length N, and VEXP will be a vector of length M.

At process block 1020, significands are determined for the DE-BBFP matrix elements. For each elements, a common exponent is selected that is the minimum of the respective element's row and column exponents. The normal floating-point significand is scaled by the difference between the common exponent and the normal floating-point exponent.

At process block 1030, the common exponents and significands determined at process blocks 1010 and 1010 are stored in memory or a computer-readable storage medium. As discussed above, the DE-BBFP format can provide substantial memory reduction over normal-precision floating-point values. In some examples, the DE-BBFP matrix values can be further reduced by quantizing exponents and/or significands or lossless compression techniques.

At process block 1040, a matrix operation is performed using the DE-BBFP matrix. The DE-BBFP matrix is converted to SE-BBFP prior to performing a matrix operation. For example, if the DE-BBFP is to be used as a left matrix, then the row exponents are used; conversely, if the DE-BBFP is to be used as a right matrix in the operation, then the column exponents are used. When used as a left matrix, the SE-BBFP exponent is calculated as the maximum of either zero and the row exponent minus the column exponent. When used as a right matrix, the SE-BBFP exponent is calculated as the maximum of either zero and the column exponent minus the row exponent. The SE-BBFP significand is computed as the dual-exponent significand shifted right by the difference between the row/column exponents. Further detail regarding converting DE-BBFP data to SE-BBFP data and performing operations is described above regarding FIG. 8.

Any suitable matrix operation can be performed using the DE-BBFP matrix (as converted to SE-BBFP). For example, matrix multiplication, as well as addition, subtraction, computing inverse matrices, or determinants can be performed. A number of operations can be performed with matrix data stored in DE-BBFP/SE-BBFP formats before converting to normal floating-point values. For example, for machine learning/deep learning applications, a series of training or inferences actions may be performed in the DE-BBFP domain before converting the values to normal floating-point values.

At process block 1050, DE-BBFP results from performing one or more matrix operations at process block 1040 are converted to normal floating-point values, for example, in float32 or bfloat16 formats. In other examples, floating-point results produced by performing DE-BBFP operations can be directly output as the floating-point format. In some examples, additional conversion of normal floating-point values is performed, depending on the particular output format selected.

### X. Converting Normal Floating-Point matrices to DE-BBFP

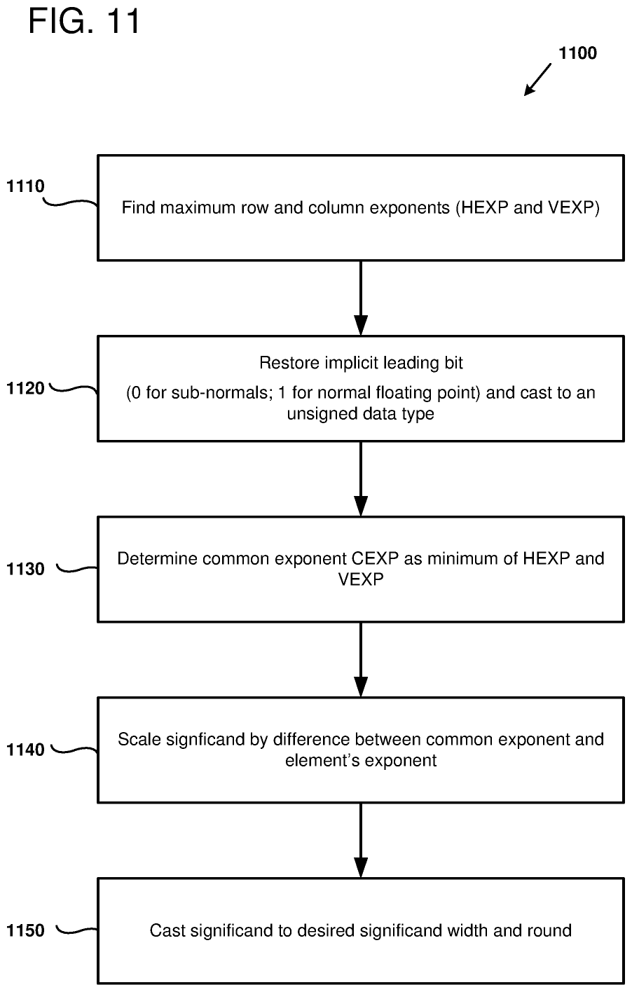

FIG. 11 is flowchart 1100 outlining an example method of converting a normal floating-point matrix to a DE-BBFP matrix. The DE-BBFP enabled system 110 discussed above regarding FIG. 1 is an example of a system that can be used to perform the illustrated method. For example, neural network operations as discussed above at FIGS. 2 and 9, including the use of number formats described above regarding FIG. 3 can be used to implement the illustrated method. As will be readily understood to a person of ordinary skill in the art having the benefit of the present disclosure, different variations of DE-BBFP systems and dual exponent formats can be adapted to perform the illustrated method.

At process block 1110, the maximum row exponents (HEXP) and column exponents (VEXP) for each row and column in a normal floating-point format input matrix are determined. Thus, for an N×M input matrix, having significands m_{i,j}, exponents e_{i,j}, and sign bits s_{i,j}, HEXP will be a vector of length N, and VEXP will be a vector of length M. The vectors can be expressed more formally as:

HEXPᵢ=MAX(e_{i,0}, . . . ,e_{i,M}) for i=0 . . . N and

VEXPⱼ=MAX(e_{0,j}, . . . ,e_{M,j}) for j=0 . . . M

At process block 1120, the implicit leading bit of the floating-point significand is restored; the leading bit is explicitly represented. If the floating-point significand is a normal floating-point value, then a 1 (one) bit will be the first bit in the dual exponent significand. If the floating-point significand is a subnormal value, then a 0 (zero) bit will be the first bit in the dual exponent significand. In some examples, a subnormal significand is indicated when the number's corresponding exponent has the smallest representable value in that format. In some examples, this subnormal condition can be indicated when all of the exponent bits for a number are zero.

The sign of the significand s_{i,j} and its exponent eᵤ are the same as the sign of its corresponding floating-point element. The significand with restored leading bit is cast to an unsigned data type.

At process block 1130, a common exponent CEXP[i],[j] is determined for each element in the input matrix x_{i,j} as MIN(HEXP[i],[j]).

At process block 1140, a process block 1140, the significand for the DE-BBFP format matrix is determined by scaling the difference between an element's common exponent CEXP[i],[j] and it normal exponent eᵤ.

At process block 1150, the significand is cast to the desired width in the DE-BBFP representation. In some examples, the significand is rounded up or down. In some examples, the significand is rounded by the rounding halfway from zero technique. In some examples, the significand is truncated.

There are a number of special cases that can be handled when converting normal floating-point to DE-BBFP. In some examples, when the input floating-point number is NaN (not a number) then the output DE-BBFP number is also NaN. In some examples, NaN in DE-BBFP can be represented with all of its shared exponent bits 1, in which case the significand bits are a don't care, as the number is NaN.

As another special case, when the input floating-point number is Infinity, then the output value in DE-BBFP is represented as NaN, with all its shared exponent bits set to 1 and the significand bits being a don't care.

As another special case, when an element's row exponent is 255 and its column exponent is 256, then the DE-BBFP element is considered NaN.

For subnormal values, a significand's implied leading bit is zero when the element's common exponent is all zeroes, or one otherwise.

When the rounding halfway from zero technique is applied, it is possible for the significand to overflow. In such cases, the elements exponent is not adjusted; rather the largest possible significand is set at the element's value. To understand this, consider the same 2×2 matrix as discussed above for the SE-BBFP example:

$$\vert \begin{matrix}4 & 256 \\ 8 & 64\end{matrix} \vert$$

The exponents are

$$\vert \begin{matrix}129 & 135 \\ 130 & 133\end{matrix} \vert$$

Then_Hexp=[135, 133], _vexp=[130, 135] and the significand is determined as follows:

$$\vert \begin{matrix}0 x 80 ≫ ( min ( 135 , 130 ) - 129 ) & 0 x 80 ≫ ( min ( 135 , 135 ) - 135 ) \\ 0 x 80 ≫ ( min ( 130 , 135 ) - 130 ) & 0 x 80 ≫ ( min ( 133 , 135 ) - 133 )\end{matrix} \vert$$

And the resulting matrix is:

$$⌈ \begin{matrix}0 x 40 & 0 x 80 \\ 0 x 80 & 0 x 20\end{matrix} ⌉$$

### XI. Converting DE-BBFP Matrices to Normal Floating-Point Format

FIG. 12 is flowchart 1200 outlining an example method of converting a DE-BBFP matrix to a normal floating-point matrix. The DE-BBFP enabled system 110 discussed above regarding FIG. 1 is an example of a system that can be used to perform the illustrated method. For example, neural network operations as discussed above at FIGS. 2 and 8, including the use of number formats described above regarding FIG. 3 can be used to implement the illustrated method. As will be readily understood to a person of ordinary skill in the art having the benefit of the present disclosure, different variations of DE-BBFP systems and dual exponent formats can be adapted to perform the illustrated method. For ease of explanation, conversion to bfloat16 floating-point numbers is discussed in this example, although any suitable normal floating-point format can be a target of the illustrated method.

At process block 1210, a common exponent CEXP for each element is selected as the minimum of that element's row exponent HEXP and column exponent VEXP. If both the element's HEXP and VEXP exponents are at the maximum value, then CEXP is set to that value. For example, for 8 bit exponents used in bfloat16, if both HEXP and VEXP are 255, then CEXP is 255.

At process block 1220, a normalized significand (NSIG) is determined by shifting the DE-BBFP significand left until its most significant bit is 1. The number of left shifts used, LS, is retained for subsequent operations.

At process block 1230, it is determined whether the element is subnormal. If the value CEXP-LS is greater than zero, then the elements is determined to be a normal floating-point value, and the method proceeds to process block 1240. If the value CEXP-LS is greater than or equal to zero, then the element is subnormal and the method proceeds to process block 1260.

At process block 1240, the normal floating-point significand is determined. The normal floating-point significand has its leading bit dropped and then that result is shifted left by one bit. For example, to convert the DE-BBFP significand to bfloat16, the most significand bit of the normalized significand NSIG is dropped and that result is shifted left by 1 bit. The bfloat16 significand can be calculated by (NSIG−0x80)<<1. The normal floating-point sign is the same value as the DE-BBFP element sign.

At process block 1250, the normal floating-point exponent is determined by calculating CEXP-LS.

If the element is determined to be subnormal at process block 1230, then the method proceeds to process block 1260. In this case, the floating-point significand is determined by right-shifting the normalized significand NSIG, determined at process block 1220, by LS-CEXP. For example, the subnormal bfloat16 format significand can be calculated as NSIG>>(LS-CEXP).

At process block 1270, the normal floating-point exponent is set to zero, indicating that the normal floating-point element is subnormal.

There are a number of special cases that can be handled when converting DE-BBFP to normal floating-point. For example, if CEXP is 255 (when converting to bfloat16), then the normal element is NaN (sign=0, exponent=255, significand=0x40). If the DE-BBFP significand is zero, then the bfloat16 output is zero.

By way of example, consider the earlier example with a DE-BBFP matrix having row exponents HEXP=[135, 133], column exponents VEXP=[130, 135] and significands of:

$$\vert \begin{matrix}0 x 40 & 0 x 80 \\ 0 x 80 & 0 x 80\end{matrix} \vert$$

The normalized significand matrix is:

$$\vert \begin{matrix}0 & 0 \\ 0 & 0\end{matrix} \vert$$

while the LS matrix (indicating number of left shifts to convert to normal floating-point significand) is:

$$\vert \begin{matrix}1 & 0 \\ 0 & 0\end{matrix} \vert$$

The normal floating-point exponents for each element are computed as

$$\vert \begin{matrix}129 = min ( 135 , 130 ) - 1 & 134 = min ( 135 , 135 ) - 0 \\ 130 = min ( 133 , 130 ) - 0 & 133 = min ( 133 , 135 ) - 0\end{matrix} \vert$$

while the significands are computed as:

$$\vert \begin{matrix}0 & 0 \\ 0 & 0\end{matrix} \vert .$$

### XII. Example Computing Environment

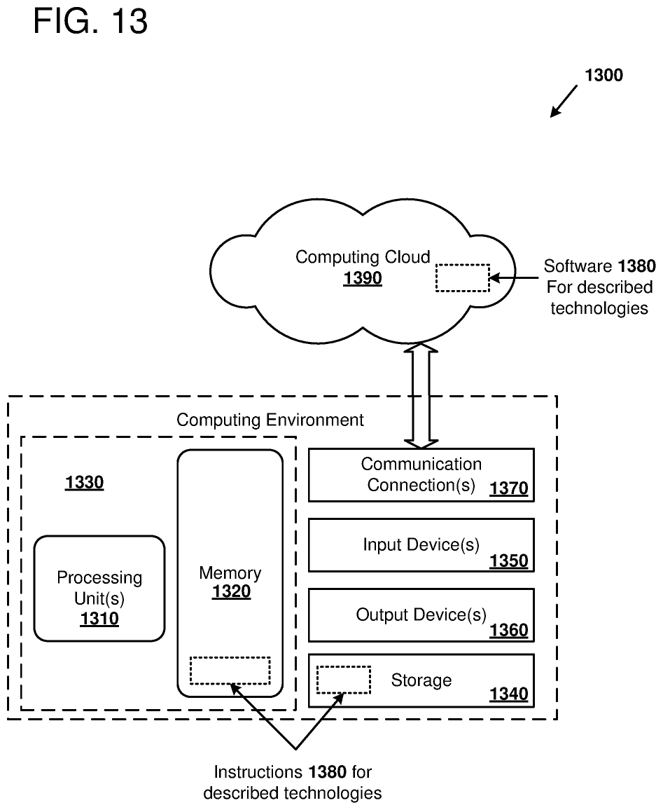

FIG. 13 illustrates a generalized example of a suitable computing environment 1300 in which described embodiments, techniques, and technologies, including performing machine learning and deep learning using dual exponent matrix formats such as those described above, can be implemented.

The computing environment 1300 is not intended to suggest any limitation as to scope of use or functionality of the technology, as the technology may be implemented in diverse general-purpose or special-purpose computing environments. For example, the disclosed technology may be implemented with other computer system configurations, including hand held devices, multi-processor systems, programmable consumer electronics, network PCs, minicomputers, mainframe computers, and the like. The disclosed technology may also be practiced in distributed computing environments where tasks are performed by remote processing devices that are linked through a communications network. In a distributed computing environment, program modules may be located in both local and remote memory storage devices.

With reference to FIG. 13, the computing environment 1300 includes at least one processing unit 1310 and memory 1320. In FIG. 13, this most basic configuration 1330 is included within a dashed line. The processing unit 1310 executes computer-executable instructions and may be a real or a virtual processor. In a multi-processing system, multiple processing units execute computer-executable instructions to increase processing power and as such, multiple processors can be running simultaneously. The memory 1320 may be volatile memory (e.g., registers, cache, RAM), non-volatile memory (e.g., ROM, EEPROM, flash memory, etc.), or some combination of the two. The memory 1320 stores software 1380, images, and video that can, for example, implement the technologies described herein. A computing environment may have additional features. For example, the computing environment 1300 includes storage 1340, one or more input devices 1350, one or more output devices 1360, and one or more communication connections 1370. An interconnection mechanism (not shown) such as a bus, a controller, or a network, interconnects the components of the computing environment 1300. Typically, operating system software (not shown) provides an operating environment for other software executing in the computing environment 1300, and coordinates activities of the components of the computing environment 1300.

The storage 1340 may be removable or non-removable, and includes magnetic disks, magnetic tapes or cassettes, CD-ROMs, CD-RWs, DVDs, or any other medium which can be used to store information and that can be accessed within the computing environment 1300. The storage 1340 stores instructions for the software 1380, plugin data, and messages, which can be used to implement technologies described herein.

The input device(s) 1350 may be a touch input device, such as a keyboard, keypad, mouse, touch screen display, pen, or trackball, a voice input device, a scanning device, or another device, that provides input to the computing environment 1300. For audio, the input device(s) 1350 may be a sound card or similar device that accepts audio input in analog or digital form, or a CD-ROM reader that provides audio samples to the computing environment 1300. The output device(s) 1360 may be a display, printer, speaker, CD-writer, or another device that provides output from the computing environment 1300.

The communication connection(s) 1370 enable communication over a communication medium (e.g., a connecting network) to another computing entity. The communication medium conveys information such as computer-executable instructions, compressed graphics information, video, or other data in a modulated data signal. The communication connection(s) 1370 are not limited to wired connections (e.g., megabit or gigabit Ethernet, Infiniband, Fibre Channel over electrical or fiber optic connections) but also include wireless technologies (e.g., RF connections via Bluetooth, WiFi (IEEE 802.11a/b/n), WiMax, cellular, satellite, laser, infrared) and other suitable communication connections for providing a network connection for the disclosed agents, bridges, and agent data consumers. In a virtual host environment, the communication(s) connections can be a virtualized network connection provided by the virtual host.

Some embodiments of the disclosed methods can be performed using computer-executable instructions implementing all or a portion of the disclosed technology in a computing cloud 1390. For example, the disclosed methods can be executed on processing units 1310 located in the computing environment 1330, or the disclosed methods can be executed on servers located in the computing cloud 1390.

Computer-readable media are any available media that can be accessed within a computing environment 1300. By way of example, and not limitation, with the computing environment 1300, computer-readable media include memory 1320 and/or storage 1340. As should be readily understood, the term computer-readable storage media includes the media for data storage such as memory 1320 and storage 1340, and not transmission media such as modulated data signals.

### XIII. Additional Examples

Additional examples are disclosed in the clauses below, which may be re-arranged in combination and subcombination with one another.

Clause 1. A computer-implemented method comprising: with a processor: selecting a common exponent for a bounding box of elements of an input matrix to be stored in a dual exponent format, the common exponent being selected based on the smaller exponent for either a row or a column of the bounding box of elements; determining significands for the bounding box of elements of a dual exponent format matrix, each of the determined significands being selected by comparing a respective element's exponent to the common exponent; and storing the determined significands and the common exponent as a dual exponent format matrix in a computer-readable storage medium.

Clause 2. The method of clause 1, wherein the selecting the common exponent comprises computing the smaller exponent for either a row or a column of the bounding box of elements less the number of left shifts to compute the normalized significands for the respective row or column of the bounding box of elements.

Clause 3. The method of clause 1 or clause 2, wherein the determining the significands comprises: left-shifting a significand in the input matrix by the difference between the common exponent and the significand's input matrix exponent.

Clause 4. The method of any one of clauses 1-3, wherein the bounding box of elements in the input matrix comprises regular floating-point elements, and wherein the determining the significands comprises: restoring an implicit leading bit from the regular floating-point significand; and scaling the regular floating-point significand by the difference between the selected common exponent and the regular floating-point exponent.

Clause 5. The method of any one of clauses 1-4, further comprising: determining a left-shift value for a significand indicating the number of shifts the most significant ‘1’ bit is from the most significant bit position; and when the left-shift value is greater than the common exponent, then determining the normal significant by right-shifting the significant by the difference between the left-shift value and the common exponent.

Clause 6. The method of any one of clauses 1-5, further comprising: determining whether the dual exponent format matrix will be used as a left-side matrix or a right-side matrix in a matrix operation; and based on the determining, converting the dual exponent format matrix to a single exponent format matrix by selecting the common exponent based on the largest exponent for the row of the bounding box of elements when the dual exponent format matrix will be used as a left-side matrix, or selecting the common exponent based on the largest exponent for the column of the bounding box of elements when the dual exponent format matrix will be used as a right-side matrix.

Clause 7. The method of any one of clauses 1-6, wherein the common exponent is a common row exponent selected based on the largest exponent for a row of the bounding box of elements, the method further comprising: selecting a common column exponent for a bounding box of elements of an input matrix to be stored in a dual exponent format, the common exponent being selected based on the largest exponent for a column of the bounding box of elements; and storing the common column exponent in the computer-readable storage medium; where each of the determined significands is selected by comparing the respective element's exponent to the larger of the common row exponent or the common column exponent.

Clause 8. The method of any one of clauses 1-7, further comprising: performing a matrix operation with the dual exponent format matrix to produce a result matrix in dual exponent format.

Clause 9. The method of clause 8, further comprising: converting the result matrix in dual exponent format to a result matrix in regular floating-point format and storing the result matrix in regular floating-point format in a computer-readable storage medium.

Clause 10. The method of any one of clauses 1-9, further comprising: quantizing the determined significands, the common exponent, or the determined significands and the common exponent.

Clause 11. The method of any one of clauses 1-10, wherein: the bounding box of elements is a 16×16 element bounding box; and the input matrix comprises a plurality of 16×16 element bounding boxs, each of the plurality of 16×16 element bounding boxs comprising a respective common exponent.

Clause 12. A method of training a neural network comprising: performing training operations for at least one layer of the neural network with the dual exponent format matrix comprising the determined significands and the common exponent produced by the method of clause 1; and storing at least one of: node weights, edge weights, bias values, or activation functions produced by the performing training operations in a computer-readable storage medium.

Clause 13. A computer-readable medium storing computer-readable instructions, which when executed by a computer, cause the computer to perform the method of any one of clauses 1-12.

Clause 14. An apparatus, comprising: a memory; a common exponent register; and a processor to: select a common exponent for a bounding box of elements of an input matrix stored in the memory, the common exponent being selected based on the largest exponent for either a row or a column of the bounding box of elements; determine significands for the bounding box of elements of a dual exponent format matrix, each of the determined significands being selected by comparing a respective element's exponent to the common exponent; and store the common exponent in the common exponent register.

Clause 15. The apparatus of clause 15, further comprising: a neural network accelerator formed from components, the components comprising the memory, the common exponent register, and the processor; and wherein the apparatus is configured to evaluate a neural network model by performing at least one training, inference, or classification operation using the dual exponent format matrix.

Clause 16. The apparatus of clause 14 or 15, further comprising: a floating-point to dual exponent bounding box-based floating-point (DE-BBFP) converter to receive regular floating-point values for the neural network model and produce the dual exponent format matrix; and a DE-BBFP to floating-point converter to produce regular floating-point values from a result dual exponent format matrix produced by performing at least one matrix operation with the produced dual exponent format matrix.

Clause 17. The apparatus of any one of clauses 14-16 being configured to perform at least one of the methods of clauses 1-12.

Clause 18. A computer-readable storage medium storing: a result matrix generated by performing a matrix operation using a dual exponent format matrix.

Clause 19. The computer-readable storage medium of clause 18, where the result matrix is a dual exponent format matrix comprising a common exponent for each row or column of a bounding box of elements in the result matrix, the result matrix being generated by performing the matrix operation with the dual exponent format matrix and another dual format matrix.

Clause 20. The computer-readable storage medium of clauses 18 or 19, where the result matrix is an array of regular floating-point numbers generated by converting a result of the matrix operation from a dual exponent format matrix.

Clause 21. The computer-readable storage medium of any one of clauses 18-20, wherein each element in a bounding box of the dual exponent format matrix has a significand, a row common exponent, and a column format exponent, the row common exponent being shared by each of the elements in a row of the bounding box, the column common exponent being shared by each of the elements in a column of the bounding box, and where the result matrix is generated by: for each element in the bounding box of the dual exponent format matrix: selecting the minimum exponent of the element's respective row common exponent and column common exponent; computing a normalized significand by shifting the element's significant left by a number of shifts until its most significant bit is a 1; computing a normalized exponent by subtracting the number of shifts from the minimum exponent; and storing the normalized significand and the normalized exponent in the result matrix in the computer-readable storage medium.

Clause 22. The computer-readable storage medium of clause 21, wherein the computing the normalized significand further comprises dropping the most significant bit and shifting the significant left based on the number of bits in the dual exponent format significand and the number of bits in the regular floating-point significand.

Clause 23. A computer-readable storage medium storing: a result matrix generated by performing a matrix operation using a dual exponent format matrix according to at least one of the methods of claims 1-12.

In view of the many possible embodiments to which the principles of the disclosed subject matter may be applied, it should be recognized that the illustrated embodiments are only preferred examples and should not be taken as limiting the scope of the claims to those preferred examples. Rather, the scope of the claimed subject matter is defined by the following claims. We therefore claim as our invention all that comes within the scope of these claims.

What is claimed is:

1. A computer-implemented method comprising:
with a processor:
selecting a common exponent for a bounding box of elements of an input matrix to be stored in a dual exponent format, the common exponent being selected based on the smaller exponent for either a row or a column of the bounding box of elements;
determining significands for the bounding box of elements of a dual exponent format matrix, each of the determined significands being selected by comparing a respective element's exponent to the common exponent; and
storing the determined significands and the common exponent as a dual exponent format matrix in a computer-readable storage medium.

2. The method of claim 1, wherein the selecting the common exponent comprises computing the smaller exponent for either a row or a column of the bounding box of elements less the number of left shifts to compute the normalized significands for the respective row or column of the bounding box of elements.

3. The method of claim 1, wherein the determining the significands comprises:
left-shifting a significand in the input matrix by the difference between the common exponent and the significand's input matrix exponent.

4. The method of claim 1, wherein the bounding box of elements in the input matrix comprises regular floating-point elements, and wherein the determining the significands comprises:
restoring an implicit leading bit from the regular floating-point significand; and
scaling the regular floating-point significand by the difference between the selected common exponent and the regular floating-point exponent.

5. The method of claim 1, further comprising:
determining a left-shift value for a significand indicating the number of shifts the most significant ‘1’ bit is from the most significant bit position; and
when the left-shift value is greater than the common exponent, then determining the normal significant by right-shifting the significant by the difference between the left-shift value and the common exponent.

6. The method of claim 1, further comprising:
determining whether the dual exponent format matrix will be used as a left-side matrix or a right-side matrix in a matrix operation; and
based on the determining, converting the dual exponent format matrix to a single exponent format matrix by selecting the common exponent based on the largest exponent for the row of the bounding box of elements when the dual exponent format matrix will be used as a left-side matrix, or selecting the common exponent based on the largest exponent for the column of the bounding box of elements when the dual exponent format matrix will be used as a right-side matrix.

7. The method of claim 1, wherein the common exponent is a common row exponent selected based on the largest exponent for a row of the bounding box of elements, the method further comprising:
selecting a common column exponent for a bounding box of elements of an input matrix to be stored in a dual exponent format, the common exponent being selected based on the largest exponent for a column of the bounding box of elements; and
storing the common column exponent in the computer-readable storage medium;
wherein each of the determined significands is selected by comparing the respective element's exponent to the larger of the common row exponent or the common column exponent.

8. The method of claim 1, further comprising:
performing a matrix operation with the dual exponent format matrix to produce a result matrix in dual exponent format.

9. The method of claim 8, further comprising:
converting the result matrix in dual exponent format to a result matrix in regular floating-point format and storing the result matrix in regular floating-point format in a computer-readable storage medium.

10. The method of claim 1, further comprising:
quantizing the determined significands, the common exponent, or the determined significands and the common exponent.

11. The method of claim 1, wherein:
the bounding box of elements is a 16×16 element bounding box; and
the input matrix comprises a plurality of 16×16 element bounding boxs, each of the plurality of 16×16 element bounding boxs comprising a respective common exponent.

12. A method of training a neural network comprising:
performing training operations for at least one layer of the neural network with the dual exponent format matrix comprising the determined significands and the common exponent produced by the method of claim 1; and
storing at least one of: node weights, edge weights, bias values, or activation functions produced by the performing training operations in a computer-readable storage medium.

13. An apparatus, comprising:
a memory;
a common exponent register; and
a processor to:
select a common exponent for a bounding box of elements of an input matrix stored in the memory, the common exponent being selected based on the largest exponent for either a row or a column of the bounding box of elements;
determine significands for the bounding box of elements of a dual exponent format matrix, each of the determined significands being selected by comparing a respective element's exponent to the common exponent; and
store the common exponent in the common exponent register.

14. The apparatus of claim 13, further comprising:
a neural network accelerator formed from components, the components comprising the memory, the common exponent register, and the processor; and
wherein the apparatus is configured to evaluate a neural network model by performing at least one training, inference, or classification operation using the dual exponent format matrix.

15. The apparatus of claim 14, further comprising:
a floating-point to dual exponent bounding box-based floating-point (DE-BBFP) converter to receive regular floating-point values for the neural network model and produce the dual exponent format matrix; and
a DE-BBFP to floating-point converter to produce regular floating-point values from a result dual exponent format matrix produced by performing at least one matrix operation with the produced dual exponent format matrix.

16. A computer-readable storage medium storing:
a result matrix generated by performing a matrix operation using a dual exponent format matrix.

17. The computer-readable storage medium of claim 16, wherein:
the result matrix is a dual exponent format matrix comprising a common exponent for each row or column of a bounding box of elements in the result matrix, the result matrix being generated by performing the matrix operation with the dual exponent format matrix and another dual format matrix.

18. The computer-readable storage medium of claim 16, wherein:
the result matrix is an array of regular floating-point numbers generated by converting a result of the matrix operation from a dual exponent format matrix.

19. The computer-readable storage medium of claim 18, wherein each element in a bounding box of the dual exponent format matrix has a significand, a row common exponent, and a column format exponent, the row common exponent being shared by each of the elements in a row of the bounding box, the column common exponent being shared by each of the elements in a column of the bounding box, and where the result matrix is generated by:
for each element in the bounding box of the dual exponent format matrix:
selecting the minimum exponent of the element's respective row common exponent and column common exponent;
computing a normalized significand by shifting the element's significant left by a number of shifts until its most significant bit is a 1;
computing a normalized exponent by subtracting the number of shifts from the minimum exponent; and
storing the normalized significand and the normalized exponent in the result matrix in the computer-readable storage medium.

20. The computer-readable storage medium of claim 19, wherein the computing the normalized significand further comprises dropping the most significant bit and shifting the significant left based on the number of bits in the dual exponent format significand and the number of bits in the regular floating-point significand.
